(19) United States
(12) Patent Application Publication
(10) Pub. No.: US 2026/0157151 A1
(43) Pub. Date: Jun. 4, 2026

(54) SUBSTRATE GRIPPER

(71) Applicant: APPLIED MATERIALS, INC., Santa Clara, CA (US)

(72) Inventors: Ioannis Oxyzoglou, London (GB); James Christopher Hansen, Mountain View, CA (US); Paul Benjamin Reuter, Austin, TX (US)

(21) Appl. No.: 19/184,672

(22) Filed: Apr. 21, 2025

(30) Foreign Application Priority Data
Dec. 4, 2024 (GR) 20240100854

(51) Int. Cl. H01L 21/683; B65G 47/91

(52) U.S. Cl. CPC H10P 72/78; B65G 47/91

(57) ABSTRACT

A substrate gripper includes a gripper body having a base configured to support a substrate by vacuum. The substrate gripper further includes a bowl-shaped collector coupled with the gripper body and configured to collect a flow of air. The substrate gripper further includes a bell-shaped flow cone coupled with the gripper body and configured to direct the flow of air toward an edge of the gripper body.

### RELATED APPLICATION

This application claims the benefit under 35 U.S.C. § 119(a) of Greek Application No. GR20240100854, filed, Dec. 4, 2024, the entire content of which is hereby incorporated by reference.

### TECHNICAL FIELD

This instant specification generally relates to a gripping device for substrates (i.e., a substrate gripper). The instant disclosure relates specifically to a substrate gripper, and methods and systems related to controlling and/or using the substrate gripper.

### BACKGROUND

Substrates are sometimes processed while supported on a substrate support. A substrate may be transported to and/or from a processing chamber. Grippers may be used to handle substrates.

### SUMMARY

In one embodiment, a substrate gripper includes a gripper body having a base configured to support a substrate by vacuum. The substrate gripper further includes a bowl-shaped collector coupled with the gripper body and configured to collect a flow of air. The substrate gripper further includes a bell-shaped flow cone coupled with the gripper body and configured to direct the flow of air toward an edge of the gripper body.

In one embodiment, a substrate gripper includes a gripper body having a base configured to support a substrate by vacuum. The substrate gripper further includes one or more proximity sensors disposed within the base of the gripper body. The one or more proximity sensors are configured to sense a distance between a bottom of the base and an object disposed beneath the gripper body.

In one embodiment, a factory interface includes a substrate gripper. The substrate gripper includes a gripper body having a base configured to support a substrate by vacuum. The substrate gripper further includes a bowl-shaped collector coupled with the gripper body and configured to collect a flow of air. The substrate gripper further includes a bell-shaped flow cone coupled with the gripper body and configured to direct the flow of air toward an edge of the gripper body.

In one embodiment, a method includes receiving sensor data indicative of a position of a substrate lifted by a lift assembly. The method further includes determining, based on the sensor data, a distance between a bottom of a substrate gripper and the substrate. The method further includes, responsive to determining the distance is within a threshold distance from the bottom of the substrate gripper, causing the lift assembly to hold the substrate at the distance. The method further includes causing the substrate gripper to grip the substrate.

In one embodiment, a system includes a substrate gripper configured to grip a substrate. The system further includes one or more proximity sensors disposed within a body of the substrate gripper. The system further includes a lift assembly configured to lift the substrate. The system further includes a controller. The controller is configured to receive, from the one or more proximity sensors, sensor data indicative of a position of the substrate lifted by the lift assembly. The controller is further configured to determine, based on the sensor data, a distance between a bottom of the substrate gripper and the substrate. The controller is further configured to, responsive to determining the distance is within a threshold distance from the bottom of the substrate gripper, cause the lift assembly to hold the substrate at the distance. The controller is further configured to cause the substrate gripper to grip the substrate.

In one embodiment, a non-transitory machine-readable storage medium includes instructions that, when executed by a processing device, cause the processing device to perform operations. The processing device is to receive first sensor data indicative of a position of a substrate lifted by a lift assembly. The processing device is further to determine, based on the sensor data, a distance between a bottom of a substrate gripper and the substrate. The processing device is further to, responsive to determining the distance is within a threshold distance from the bottom of the substrate gripper, cause the lift assembly to hold the substrate at the distance. The processing device is further to cause the substrate gripper to grip the substrate.

In one embodiment, a method includes causing a robot to present a substrate at an assembly station. The method further includes receiving image data associated with a position of a center of the substrate. The method further includes determining, based on the image data, an offset associated with the position of the center of the substrate with respect to a target position for the substrate. The method further includes causing, based on the offset, the robot to adjust the position of the center of the substrate to an adjusted position. The method further includes causing the robot to place the substrate at the assembly station with the adjusted position.

In one embodiment, a system includes an assembly station configured to combine a substrate with a substrate support. The system further includes one or more imaging devices. The system further includes a robot configured to individually and collectively handle the substrate and the substrate support. The system further includes a controller. The controller is configured to cause the robot to present the substrate at the assembly station. The controller is further configured to receive, from the one or more imaging devices, image data associated with a position of a center of the substrate. The controller is further configured to determine, based on the image data, an offset associated with the position of the center of the substrate with respect to a target position for the substrate. The controller is further configured to cause, based on the offset, the robot to adjust the position of the center of the substrate to an adjusted position. The controller is further configured to cause the robot to place the substrate at the assembly station with the adjusted position.

In one embodiment, a non-transitory machine-readable storage medium includes instructions that, when executed by a processing device, cause the processing device to perform operations. The processing device is to cause a robot to present a substrate at an assembly station. The processing device is further to receive image data associated with a position of a center of the substrate. The processing device is further to determine, based on the image data, an offset associated with the position of the center of the substrate with respect to a target position for the substrate. The processing device is further to cause, based on the offset, the robot to adjust the position of the center of the substrate to an adjusted position. The processing device is further to cause the robot to place the substrate at the assembly station with the adjusted position.

In one embodiment, a factory interface includes a storage station configured to store multiple substrate supports. The factory interface further includes a robot configured to retrieve a substrate support of the multiple substrate supports from the storage station and further configured to retrieve a substrate from an enclosure system coupled with the factory interface. The factory interface further includes an assembly station configured to separately receive the substrate and the substrate support from the robot and further configured to assemble the substrate to the substrate support. The assembly station includes a gripper configured to grip the substrate and to place the substrate on the substrate support.

In one embodiment, a method includes retrieving, by a robot disposed within a factory interface chamber, a substrate from an enclosure system coupled with the factory interface chamber. The method further includes providing, by the robot, the substrate to an assembly station. The method further includes retrieving, by the robot, a substrate support from a storage station associated with the factory interface chamber. The method further includes providing, by the robot, the substrate support to the assembly station. The method further includes, assembling, by the assembly station, the substrate to the substrate support. The method further includes providing, by the robot, the substrate support carrying the substrate to a load lock chamber coupled with the factory interface chamber. The load lock chamber is coupled with a processing system for processing of the substrate.

In one embodiment, a system includes a factory interface at least partially forming a factory interface chamber. The system further includes a processing system associated with the factory interface, the processing system including at least one processing chamber. The system further includes a load lock forming a load lock chamber coupled with the factory interface chamber and the processing system. The system further includes a robot disposed within the factory interface chamber. The robot is configured to retrieve a substrate support from a storage station associated with the factory interface and further configured to retrieve a substrate from an enclosure system coupled with the factory interface. The system further includes an assembly station disposed within the factory interface chamber. The assembly station is configured to separately receive the substrate and the substrate support from the robot and further configured to assemble the substrate to the substrate support. The assembly station includes a gripper configured to grip the substrate and to place the substrate on the substrate support.

### BRIEF DESCRIPTION OF THE DRAWINGS

Aspects and embodiments of the present disclosure will be understood more fully from the detailed description given below and from the accompanying drawings of various aspects and embodiments of the disclosure, which, however, should not be taken to limit the disclosure to the specific aspects or embodiments, but are for explanation and understanding only. The drawings, described below, are for illustrative purposes and are not necessarily drawn to scale.

FIG. 1A illustrates a schematic view of an example manufacturing system (e.g., a substrate processing system), in accordance with some embodiments of the present disclosure.

FIG. 1B illustrates a schematic side view of an example factory interface, in accordance with some embodiments of the present disclosure.

FIG. 2A-2G illustrate example schematic views of an example assembly station including a substrate gripper, in accordance with some embodiments of the present disclosure.

FIG. 3 illustrates a simplified perspective view of a substrate support, in accordance with some embodiments of the present disclosure.

FIGS. 4A-C illustrate depictions of air flow proximate to a substrate gripper, in accordance with some embodiments of the present disclosure.

FIGS. 5A-D are flow diagrams of example methods for controlling a substrate gripper using proximity sensors, in accordance with some embodiments of the present disclosure.

FIGS. 6A-C are flow diagrams of example methods for controlling the placement of a substrate at a substrate assembly station using image sensors, in accordance with some embodiments of the present disclosure.

FIGS. 7A-D are flow diagrams of example methods for assembling a substrate to a substrate support, in accordance with some embodiments of the present disclosure.

FIG. 8 is a block diagram illustrating a computer system, according to aspects of the present disclosure.

### DETAILED DESCRIPTION

Semiconductor device manufacturing and other device manufacturing (e.g., such as for displays, photovoltaic devices, etc.) often involves tens and even hundreds of complex operations to implement raw substrate (e.g., wafer) preparation, polishing, material deposition, etching, and the like. Substrates delivered for processing in processing chambers can include bare substrates (e.g., silicon substrates, quartz substrates, Gallium Arsenide substrates, corundum substrates), substrates that have been preprocessed (e.g., covered with one or more films, such as carbon films), or substrates that have already undergone one or more processing operations (e.g., deposition, patterning, etching, and so on). In some embodiments, substrates are transported to and/or from a processing chamber while supported on a substrate support, such as a susceptor. The substrate is placed on the substrate support prior to processing and is removed from the substrate support after processing.

In some embodiments, a substrate support, such as a susceptor, includes a recessed pocket in which a substrate sits. The substrate support may include a raised rim surrounding the substrate. The top of the substrate may sit substantially flat with the rim of the substrate support, blocking the edges of the substrate. In some embodiments, a substrate gripper may grip the edges of the substrate. However, where the edges of the substrate are blocked (e.g., by the raised rim of the substrate support), a conventional edge-grip cannot be used. Therefore, separating a substrate from a substrate support or assembling a substrate to a substrate support as described herein may prove difficult. Some solutions include contacting the top surface of a substrate. However, contacting the top surface of a substrate can damage the substrate. In instances where the structures and/or features formed on the top of the substrate are fragile, contacting the top surface of the substrate can contaminate the substrate and/or cause irreparable damage. In some embodiments, other solutions to the above-described problem include using vacuum or Bernoulli-principle handlers to lift substrates from substrate supports. In some embodiments, vacuum handlers generate a vacuum to “suck” the substrate upwards. Vacuum handlers often, though, contact the top side of the substrate. Such top-side substrate contact may not be feasible without damaging some substrates. Bernoulli-principle handlers exhaust high-velocity air to create a low pressure region for a lifting force, but also create an air cushion between the gripper and the substrate to prevent contact. However, some vacuum and Bernoulli-principle handlers stir up particles which then contaminate the substrate. In either instance, the substrate may be scrapped if contaminated.

Aspects and embodiments of the present disclosure address the above-described problem and shortcomings of previous solutions by providing an assembly station within a factory interface, the assembly station having a substrate gripper configured to assemble a substrate to a substrate support (e.g., to place a substrate on a substrate support) and/or to separate the substrate from the substrate support. Note that though a substrate gripper is described herein as being in a factory interface, the substrate gripper described herein may also be installed at other locations, such as in a process chamber, in a transfer chamber, in a passthrough chamber, in a load lock chamber, and so on.

In some embodiments, the substrate gripper described herein uses vacuum to handle the substrate without the top surface of the substrate contacting the gripper. In some embodiments, a sonotrode on a bottom of the substrate gripper may emit ultrasonic vibrations that may repel the substrate away from the bottom of the gripper, while the substrate gripper provides a vacuum to attract the substrate to the bottom of the gripper. The ultrasonic vibrations from the sonotrode may prevent the top of the substrate from contacting the bottom of the gripper when the vacuum is active (e.g., because of the emitted ultrasonic vibrations), while the vacuum continues to exert a force to push or pull the substrate towards the substrate gripper.

In some embodiments, the substrate gripper includes one or more (e.g., three, etc.) sensors used to determine a distance between a bottom of the substrate gripper and one or more objects below the gripper (e.g., a substrate and/or a substrate support such as a susceptor). For example, reflective sensors included in/on the substrate gripper can be used to determine the distance between the bottom of the gripper and the top surface of a substrate and/or a substrate support. In some embodiments, the sensor data collected by the sensor(s) is used to determine when to stop raising a substrate and/or substrate support to the bottom of the gripper, and/or to determine whether the substrate is properly placed/located in the pocket of the substrate support. In some embodiments, while a lifter lifts the substrate to the substrate gripper, a controller receives sensor data indicative of the position of the substrate. Upon determining that the top surface of the substrate is within a threshold distance from the bottom of the substrate gripper, the controller may cause the lifter to hold the substrate at that distance. The controller may then cause the gripper to grip the substrate.

In some embodiments, placement of the substrate at the assembly station is controlled using image sensors (e.g., such as cameras). Misalignment of the substrate center may be corrected by comparing the position of the substrate center to a target position. Image sensors may capture image data indicative of the edge(s) of the substrate when the substrate is presented at the assembly station (e.g., by a substrate-handling robot). Based on the position of the substrate center determined from the image data, a controller may determine an offset of the center of the substrate with respect to a target position for the substrate. The controller may cause the robot to adjust the position of the substrate to an adjusted position (e.g., to correct for any misalignment). The controller may then cause the robot to place the substrate at the assembly station with the adjusted position. The substrate can then be lifted (e.g., by a lifter of the assembly station) to the substrate gripper and gripped by the gripper.

In some embodiments, to avoid particle contamination of the substrate, the substrate gripper includes an airflow collector and/or a cone to generate a flow of air proximate the gripper that may prevent particles from contaminating a gripped substrate. In some embodiments, a bowl-shaped collector is disposed substantially above and/or around the substrate gripper. The bowl-shaped collector may collect downward flowing air (e.g., clean dry air, or an inert gas such as argon or helium, etc.) and direct the flowing air centrally in the collector. The bowl-shaped collector may form a central hole through which the top of the substrate gripper may protrude. In some embodiments, the air flow is directed out of the central hole of the collector and downward around the substrate gripper. The substrate gripper may include a bell-shaped flow cone around the body of the gripper. The flow cone may direct the downward flow of air toward the edges of the gripper, and therefore also toward the edges of the substrate and/or the substrate support. The flow of air may radiate outwards from the flow cone, carrying particles away from the substrate and/or away from the substrate gripper. In some embodiments, a portion of the flow of air may curve around the edge of the flow cone and flow between the top surface of the substrate and the bottom of the substrate gripper toward the center of the substrate gripper. This portion of air flow may be sucked into the gripper by the vacuum source. In some embodiments, the portion of air flow is substantially particle-free.

Aspects and embodiments of the present disclosure may result in technological advances. For example, the substrate gripper described herein is capable of assembling a substrate onto a substrate support and/or separating a substrate from a substrate support without contacting the top surface of the substrate. The bowl-shaped collector and/or the bell-shaped flow cone may allow for the use of vacuum to grip the substrate without introducing particles to the top surface of the substrate. Additionally, the sensors of the substrate gripper provide for an accurate way to measure the distance between the substrate and the gripper, which can be used to avoid inadvertent collisions between the substrate and the gripper. Moreover, the image sensors can provide for accurate placement and/or alignment of the substrate in the assembly station so that the substrate can be accurately placed on a substrate support. Accordingly, the substrate gripper described herein can lead to a reduction in defects and a lower substrate scrap rate.

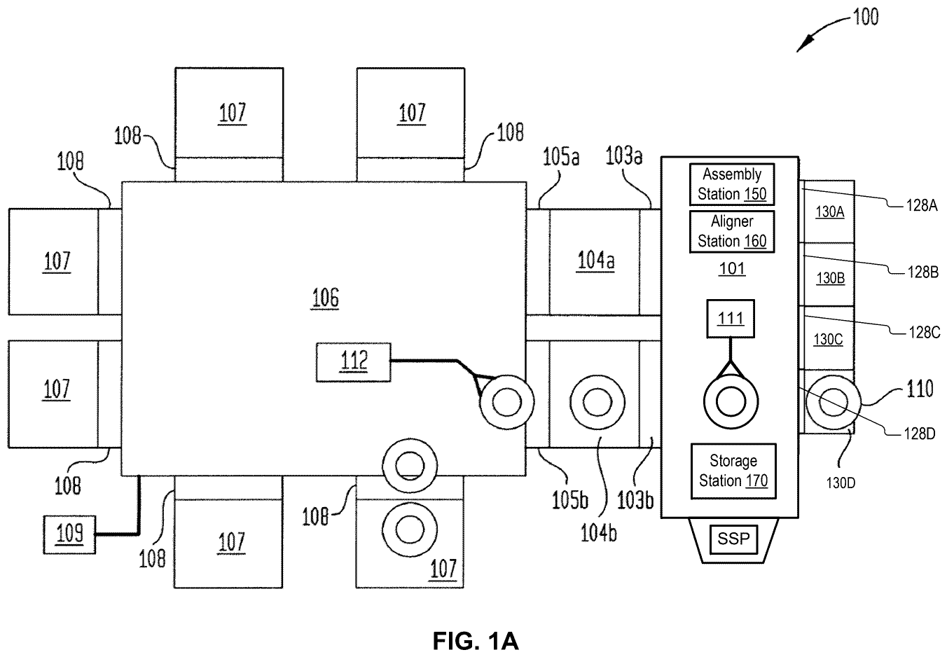

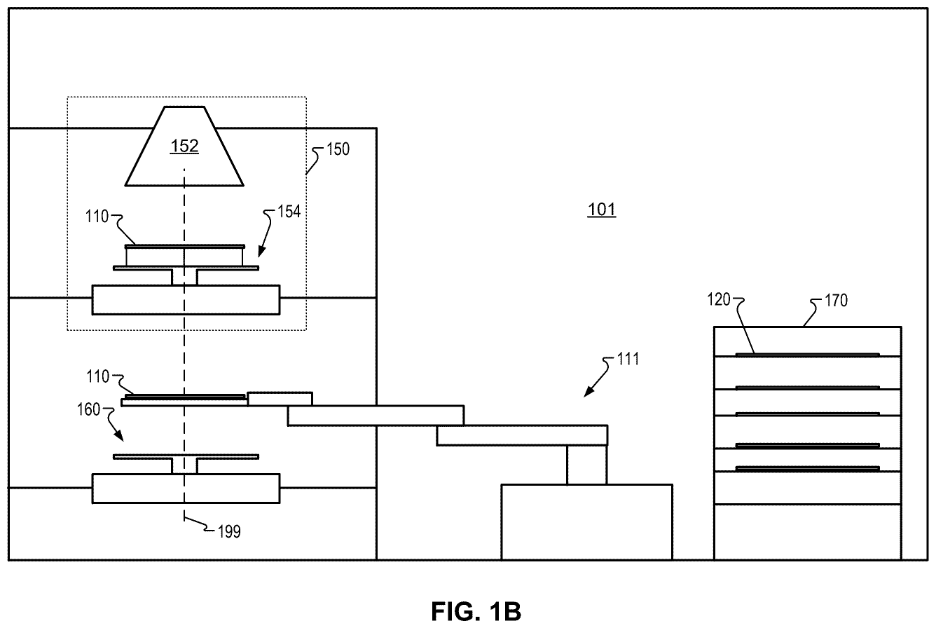

FIG. 1A illustrates a schematic view of an example manufacturing system 100 (e.g., a substrate processing system), in accordance with some embodiments of the present disclosure. The manufacturing system 100 includes a factory interface (FI) 101 and load ports 128x (e.g., load ports 128A-D). In some embodiments, the load ports 128A-D are directly mounted to (e.g., sealed against) FI 101. Enclosure systems 130x (e.g., cassette, FOUP, process kit enclosure system, or the like) are configured to removably couple (e.g., dock) to the load ports 128A-D. In some embodiments, enclosure system 130A is coupled to load port 128A, enclosure system 130B is coupled to load port 128B, enclosure system 130C is coupled to load port 128C, and enclosure system 130D is coupled to load port 128D. In some embodiments, one or more enclosure systems 130x are coupled to the load ports 128x for transferring substrates and/or other items into and out of the processing manufacturing system 100. Each of the enclosure systems 130x may seal against a respective load port 128x. In some embodiments, a first enclosure system 130A is docked to a load port 128A. Once such operation or operations are performed, the first enclosure system 130A is undocked from the load port 128A, and then a second enclosure system 130x (e.g., a FOUP containing substrate(s)) is docked to the same load port 128A. In some embodiments, an enclosure system 130x (e.g., enclosure system 130A) is a system for performing a calibration operation or a diagnostic operation.

In some embodiments, a load port 128x includes a front interface that forms an opening. The load port 128x additionally includes a horizontal surface for supporting an enclosure system 130x. Each enclosure system 130x has a front interface that forms a vertical opening. The front interface of the enclosure system 130x is sized to interface with (e.g., seal to) the front interface of the load port 128x (e.g., the vertical opening of the enclosure system 130x is approximately the same size as the vertical opening of the load port 128x). The enclosure system 130x is placed on the horizontal surface of the load port 128x and the vertical opening of the enclosure system 130x aligns with the vertical opening of the load port 128x. The front interface of the enclosure system 130x interconnects with (e.g., clamp to, be secured to, be sealed to) the front interface of the load port 128x. A bottom plate (e.g., base plate) of the enclosure system 130x has features (e.g., load features, such as recesses or receptacles, that engage with load port kinematic pin features, a load port feature for pin clearance, and/or an enclosure system docking tray latch clamping feature) that engage with the horizontal surface of the load port 128x. The same load ports 128x that are used for different types of enclosure systems 130x.

In some embodiments, the manufacturing system 100 also includes first vacuum ports 103a, 103b coupling FI 101 to respective degassing chambers 104a, 104b. Second vacuum ports 105a, 105b are coupled to respective degassing chambers 104a, 104b and disposed between the degassing chambers 104a, 104b and a transfer chamber 106 to facilitate transfer of substrates and other substrate 110 (e.g., substrate supports such as susceptors, etc.) into the transfer chamber 106. In some embodiments, a manufacturing system 100 includes and/or uses one or more degassing chambers 104 and a corresponding number of vacuum ports 103, 105 (e.g., a manufacturing system 100 includes a single degassing chamber 104, a single first vacuum port 103, and a single second vacuum port 105). The transfer chamber 106 includes a plurality of processing chambers 107 (e.g., four processing chambers 107, six processing chambers 107, etc.) disposed therearound and coupled thereto. The processing chambers 107 are coupled to the transfer chamber 106 through respective ports 108, such as slit valves or the like. In some embodiments, FI 101 is at a higher pressure (e.g., atmospheric pressure) and the transfer chamber 106 is at a lower pressure (e.g., vacuum). Each degassing chamber 104 (e.g., load lock, pressure chamber) has a first door (e.g., first vacuum port 103) to seal the degassing chamber 104 from FI 101 and a second door (e.g., second vacuum port 105) to seal the degassing chamber 104 from the transfer chamber 106. Content is to be transferred from FI 101 into a degassing chamber 104 while the first door is open and the second door is closed, the first door is to close, the pressure in the degassing chamber 104 is to be reduced to match the transfer chamber 106, the second door is to open, and the content is to be transferred out of the degassing chamber 104. A local center finding (LCF) device is to be used to align the content in the transfer chamber 106 (e.g., before entering a processing chamber 107, after leaving the processing chamber 107).

In some embodiments, the processing chambers 107 includes or more of etch chambers, deposition chambers (including atomic layer deposition, chemical vapor deposition, physical vapor deposition, or plasma enhanced versions thereof), anneal chambers, or the like.

Factory interface 101 includes a factory interface robot 111. Factory interface robot 111 includes a robot arm, such as a selective compliance assembly robot arm (SCARA) robot. Examples of a SCARA robot include a 2 link SCARA robot, a 3 link SCARA robot, a 4 link SCARA robot, and so on. The factory interface robot 111 includes an end effector on an end of the robot arm. The end effector is configured to pick up and handle specific objects, such as substrates (e.g., wafers). Alternatively, or additionally, the end effector is configured to handle objects such as a substrate support (e.g., a susceptor), which may or may not have a substrate disposed thereon. Accordingly, in some embodiments, substrate supports and supported substrates (or other objects, etc.) may be transferred together by the robot arm. The robot arm has one or more links or members (e.g., wrist member, upper arm member, forearm member, etc.) that are configured to be moved to move the end effector in different orientations and to different locations.

The factory interface robot 111 is configured to transfer objects (e.g., substrates, substrate supports, or combinations thereof) between enclosure systems 130x (e.g., cassettes, FOUPs) and degassing chambers 104a, 104b (or load ports). The factory interface robot 111 is taught a fixed location relative to a load port 128x using the enclosure system 130x in embodiments. The fixed location in one embodiment corresponds to a center location of an enclosure system 130A placed at a particular load port 128x, which in embodiments also corresponds to a center location of an enclosure system 130B placed at the particular load port 128x. Alternatively, the fixed location may correspond to other fixed locations within the enclosure system 130x, such as a front or back of the enclosure system 130x. The factory interface robot 111 is calibrated using the enclosure system 130x in some embodiments. The factory interface robot 111 is diagnosed using the enclosure system 130x in some embodiments.

In some embodiments, factory interface 101 includes an assembly station 150. The assembly station 150 may include a lifter and a substrate gripper. The lifter may lift substrates and/or other objects (e.g., such as substrate supports, etc.) to the substrate gripper. The substrate gripper and the lifter may work together to assemble a substrate to a substrate support and/or to separate a substrate from a substrate support. The factory interface robot 111 may provide the substrate and/or substrate support to the assembly station 150 for assembling of the substrate to the substrate support and/or for separating the substrate from the substrate support.

In some embodiments, the substrate gripper of the assembly station 150 grips a substrate by vacuum. In some embodiments, the substrate gripper includes multiple arms (e.g., spider arms) to grip the edge(s) of a substrate. The substrate gripper of assembly station 150 may be fixed within the factory interface 101. The substrate gripper may include a bowl-shaped flow collector and/or a bell-shaped flow cone as described herein.

In some embodiments, the factory interface robot 111 is configured to separately provide a substrate and a substrate support to one or more stations within the factory interface 101. For example, the factory interface robot 111 may retrieve a substrate from an enclosure system 130x and provide the substrate to an aligner station and/or to the assembly station 150. Similarly, the factory interface robot 111 may retrieve a substrate support 120 from the storage station 170 and provide the substrate support 120 to the assembly station 150. The factory interface robot 111 may retrieve an assembled substrate and substrate support (e.g., the substrate assembled to the substrate support) from the assembly station and provide the substrate and substrate support to a degassing chamber 104. Similarly, the factory interface robot 111 may retrieve a substrate and substrate support from a degassing chamber 104 and provide the substrate and substrate support to the assembly station 150. At the assembly station 150, the substrate may be separated from the substrate support. The factory interface robot 111 may retrieve the substrate support from the assembly station 150 and provide the substrate support to the storage station 170. The factory interface may retrieve the substrate from the assembly station 150 and provide the substrate to an enclosure system 130x.

The storage station 170 may include multiple shelves for storing objects such as substrates and/or substrate supports. In some embodiments, the storage station 170 is disposed within a chamber formed by one or more walls of the factory interface 101 (e.g., within the factory interface chamber). Alternatively, the storage station 170 may be coupled to the side of the factory interface 101 or on the back of the factory interface 101. The factory interface robot 111 may retrieve and/or place objects in the storage station 170. In some embodiments, the storage station 170 stores substrate supports and/or cover substrates for covering the substrate supports such as during cleaning operation(s) performed with respect to the substrate supports. The cover substrates may be configured to be assembled to one of the substrates supports for cleaning of the substrate supports to avoid damaging the pockets of the substrate supports.

In some embodiments, the factory interface robot 111 is configured to provide a substrate to the assembly station 150. Referring to FIG. 1B, a schematic side view of an example factory interface 101 is shown, in accordance with some embodiments of the present disclosure. The substrate gripper 152 of the assembly station 150 may be positioned above the substrate 110 when the substrate 110 is provided to the assembly station 150. A lifter 154 of the assembly station 150 may lift the substrate 110 to the substrate gripper 152. When the substrate 110 is within a threshold distance of the bottom of the gripper 152, a vacuum of the substrate gripper 152 may activate to grip the substrate 110. The lifter 154 may then lift a substrate support (e.g., a susceptor, not shown) to the substrate gripper 152. When the substrate support is within a threshold distance of the substrate 110, the vacuum of the substrate gripper 152 may be deactivated and the substrate 110 placed on the substrate support. The assembled substrate and substrate support may be lowered away (e.g., by the lifter 154) from the substrate gripper 152.

Similarly, in some embodiments, the factory interface robot 111 is configured to provide an assembled substrate and substrate support (e.g., a substrate supported on a substrate support) to the assembly station 150. The lifter 154 of the assembly station 150 may lift the substrate and substrate support to the substrate gripper 152. When the substrate 110 is within a threshold distance of the bottom of the gripper 152, a vacuum of the substrate gripper 152 may activate to grip the substrate 110. The substrate support may not be gripped by the gripper 152. The lifter 154 may lower the substrate support away from the substrate 110 to separate the substrate 110 from the substrate support. In some embodiments, the factory interface robot 111 transports the substrate support to a storage station 170 (e.g., separate from the substrate) while the substrate gripper 152 holds (e.g., grips) the substrate 110. The lifter 154 may rise to the substrate 110 gripped by the gripper 152 and the gripper 152 may un-grip the substrate 110 to place the substrate 110 on the lifter 154. The factory interface robot 111 may retrieve the substrate 110 from the lifter 154 and transport the substrate 110 to one of the enclosure systems 130x separate from the substrate support.

The assembly station 150 may include one or more proximity sensors and/or image sensors for collecting data associated with the substrate 110, such as position data, etc. The proximity sensors may be disposed within the base of the substrate gripper 152. Data from proximity sensors in the substrate gripper 152 may be used to control the lifting of the substrate 110 as described herein below. Data from image sensors may be used to control the placement of the substrate 110 on the lifter 154 as described herein below. In some embodiments, a proximity sensor may include a definitive-reflective fiber optic sensor. The proximity sensor may be capable of detecting a clear substrate material (e.g., a clear SiC substrate material). In some embodiments, the term “proximity sensor” as used herein may be used to describe a distance sensor, such as a confocal laser-type distance sensor.

Referring again to FIG. 1A, in embodiments, the assembly station 150 may be used to place substrates on substrate supports and/or to remove substrates from substrate supports. A substrate support with a supported substrate may be moved to the assembly station 150, which may remove the substrate from the substrate support. Similarly, a substrate may be moved to the assembly station 150. The substrate gripper of the assembly station 150 may grip the substrate, lifting the substrate from a robot arm 111. The robot arm (or another robot arm) may then move a substrate support to the assembly station 150, and the substrate gripper of the assembly station 150 may release the substrate onto the substrate support, after which the robot arm 111 may move the substrate support and substrate together (e.g., to a degassing chamber 104a, 104b for transfer to a process chamber and processing therein).

The manufacturing system 100 includes an aligner station 160 to align the substrates 110 and/or one or more other objects, etc. The aligner station 160 may be disposed within the factory interface. Referring again to FIG. 1B, in some embodiments, the aligner station 160 is disposed coaxial with the lifter 154 and/or substrate gripper 152. The aligner station 16, the lifter 154, and/or the substrate gripper 152 may be disposed along a vertical axis 199. The aligner station 160, the lifter 154, and/or the substrate gripper 152 may be disposed coaxially to mitigate thermal effects (e.g., effects from thermal expansion of the robot arms(s), etc.). For example, a robot arm may expand (e.g., lengthen) as its temperature increases. The movement of the robot arm may be adjusted to account for thermal expansion. By aligning the aligner station 160 coaxial with the lifter 154 and/or the substrate gripper 152, correction in robot movements may be made only once with respect to the aligner station 160, the lifter 154 and/or the substrate gripper 152. Therefore, thermal correction for robot pick and/or place movements may be mitigated.

Referring again to FIG. 1A, transfer chamber 106 includes a transfer chamber robot 112. Transfer chamber robot 112 includes a robot arm with an end effector at an end of the robot arm. The end effector is configured to handle particular objects, such as wafers. In some embodiments, the transfer chamber robot 112 is a SCARA robot, but may have fewer links and/or fewer degrees of freedom than the factory interface robot 111 in some embodiments.

A controller 109 controls various aspects of the manufacturing system 100. The controller 109 is and/or includes a computing device such as a personal computer, a server computer, a programmable logic controller (PLC), a microcontroller, and so on. The controller 109 includes one or more processing devices, which, in some embodiments, are general-purpose processing devices such as a microprocessor, central processing unit, or the like. More particularly, in some embodiments, the processing device is a complex instruction set computing (CISC) microprocessor, reduced instruction set computing (RISC) microprocessor, very long instruction word (VLIW) microprocessor, or a processor implementing other instruction sets or processors implementing a combination of instruction sets. In some embodiments, the processing device is one or more special-purpose processing devices such as an application specific integrated circuit (ASIC), a field programmable gate array (FPGA), a digital signal processor (DSP), network processor, or the like. In some embodiments, the controller 109 includes a data storage device (e.g., one or more disk drives and/or solid state drives), a main memory, a static memory, a network interface, and/or other components. In some embodiments, the controller 109 executes instructions to perform any one or more of the methods or processes described herein. The instructions are stored on a computer readable storage medium, which include one or more of the main memory, static memory, secondary storage and/or processing device (during execution of the instructions). The controller 109 receives signals from and sends controls to factory interface robot 111 and wafer transfer chamber robot 112 in some embodiments.

According to one aspect of the disclosure, to transfer substrate 110 (e.g., a substrate) into a processing chamber 107, the substrate 110 is removed from an enclosure system 130B via factory interface robot 111 located in FI 101. The factory interface robot 111 and/or assembly station 150 may place the substrate 110 on a support (e.g., a substrate support, a susceptor, etc.) and transfers the substrate 110 through one of the first vacuum ports 103a, 103b and into a respective degassing chamber 104a, 104b. A transfer chamber robot 112 located in the transfer chamber 106 removes the substrate 110 from one of the degassing chambers 104a, 104b through a second vacuum port 105a or 105b. The transfer chamber robot 112 moves the substrate 110 into the transfer chamber 106, where the substrate 110 is transferred to a processing chamber 107 through a respective port 108. After processing, the processed substrate 110 (e.g., a substrate supported on a substrate support and/or susceptor, etc.) is removed from the manufacturing system 100 in reverse of any manner described herein.

The manufacturing system 100 includes chambers, such as FI 101 (e.g., equipment front end module, EFEM) and adjacent chambers (e.g., load port 128x, enclosure system 130x, SSP, degassing chamber 104 (such as a loadlock chamber), or the like) that are adjacent to FI 101. Some or all of the chambers can be sealed. In some embodiments, inert gas (e.g., one or more of nitrogen, argon, neon, helium, krypton, or xenon) is provided into one or more of the chambers (e.g., FI 101 and/or adjacent chambers) to provide one or more inert environments. In some examples, FI 101 is an inert EFEM that maintains the inert environment (e.g., inert EFEM minienvironment) within FI 101 so that users do not need to enter FI 101 (e.g., the manufacturing system 100 is configured for no manual access within FI 101).

In some embodiments, gas flow (e.g., inert gas, nitrogen) is provided into one or more chambers (e.g., FI 101) of the manufacturing system 100. In some embodiments, the gas flow is greater than leakage through the one or more chambers to maintain a positive pressure within the one or more chambers. In some embodiments, the inert gas within FI 101 is recirculated. In some embodiments, a portion of the inert gas is exhausted. In some embodiments, the gas flow of non-recirculated gas into FI 101 is greater than the exhausted gas flow and the gas leakage to maintain a positive pressure of inert gas within FI 101. In some embodiments, FI 101 is coupled to one or more valves and/or pumps to provide the gas flow into and out of FI 101. A processing device (e.g., of controller 109) controls the gas flow into and out of FI 101. In some embodiments, the processing device receives sensor data from one or more sensors (e.g., oxygen sensor, moisture sensor, motion sensor, door actuation sensor, temperature sensor, pressure sensor, etc.) and determines, based on the sensor data, the flow rate of inert gas flowing into and/or out of FI 101.

The enclosure system 130x seals to the load port 128x responsive to being docked on the load port 128x. The enclosure system 130x provides purge port access so that the interior of the enclosure system 130x can be purged prior to opening the enclosure system 130x to minimize disturbance of the inert environment within FI 101.

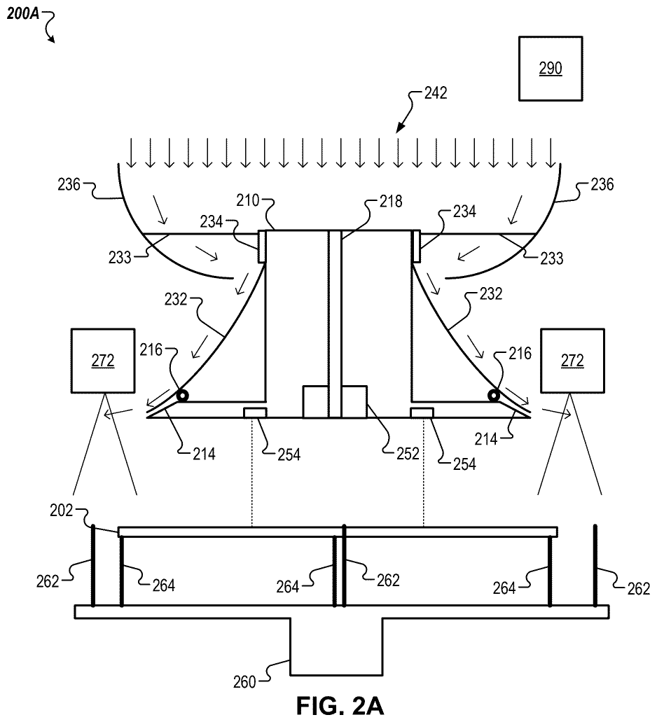

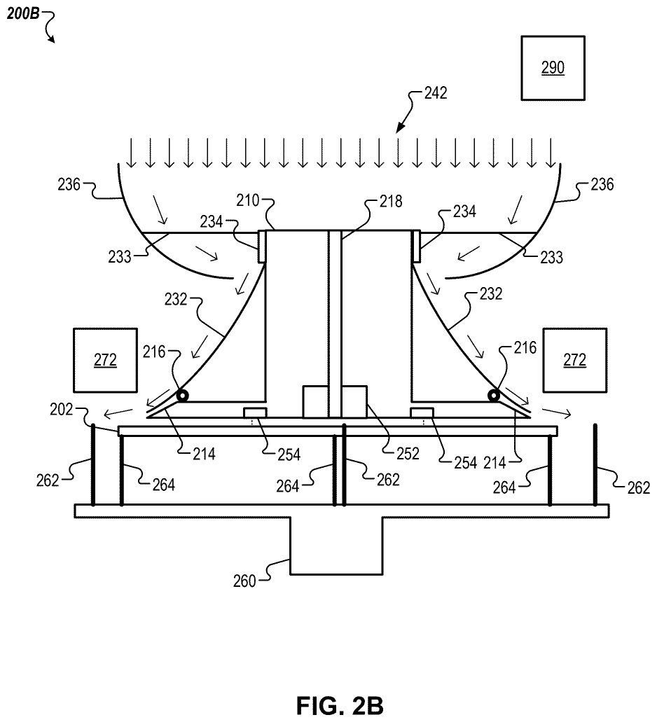

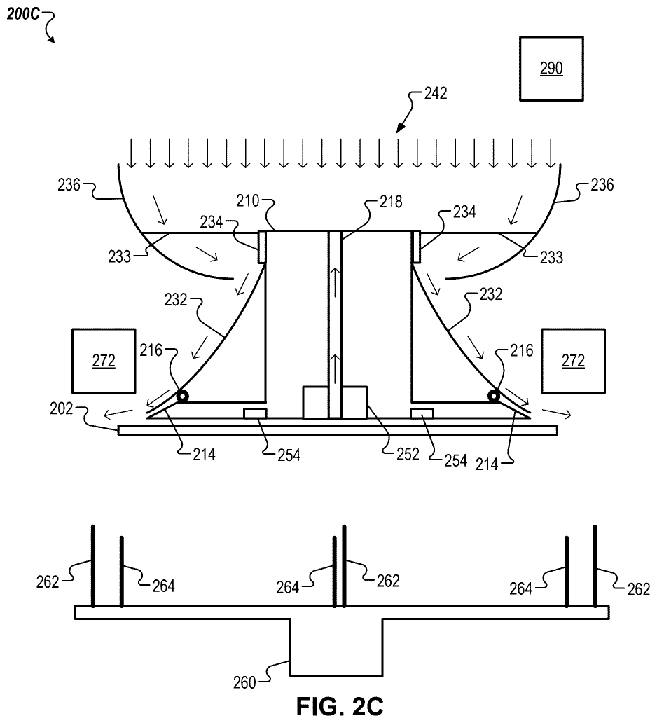

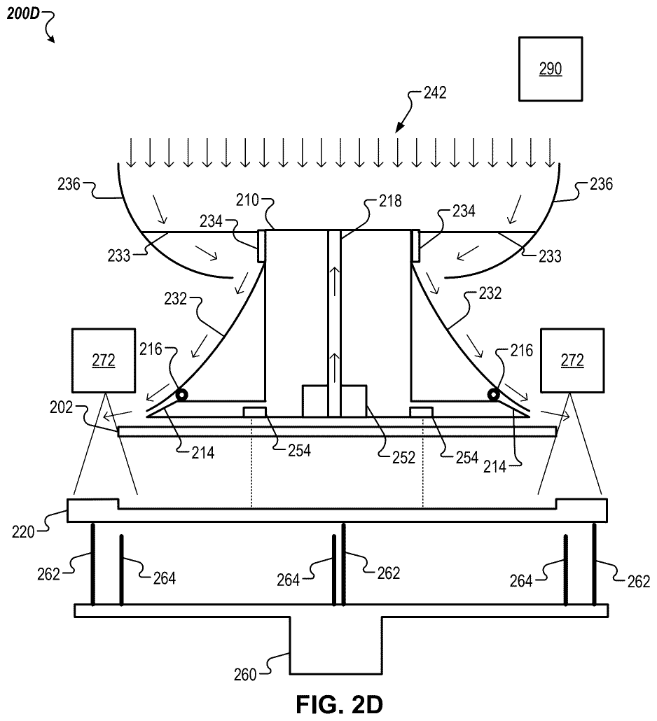

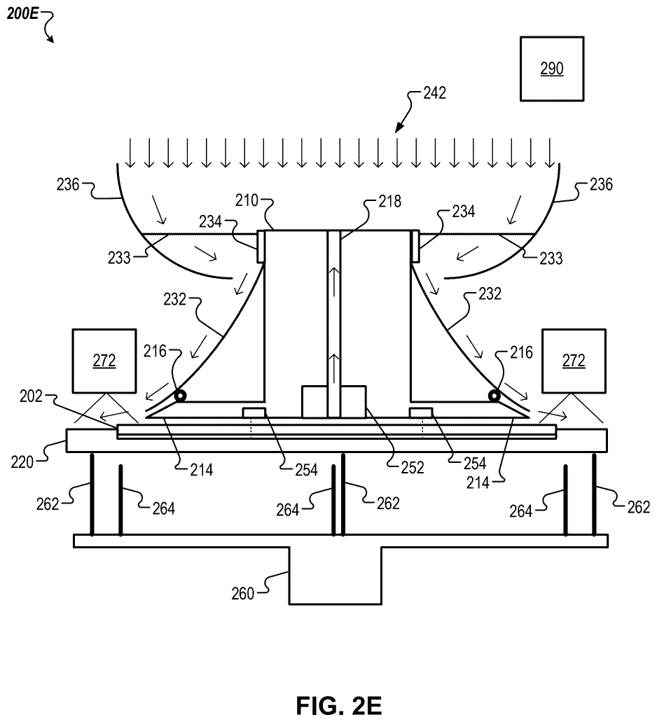

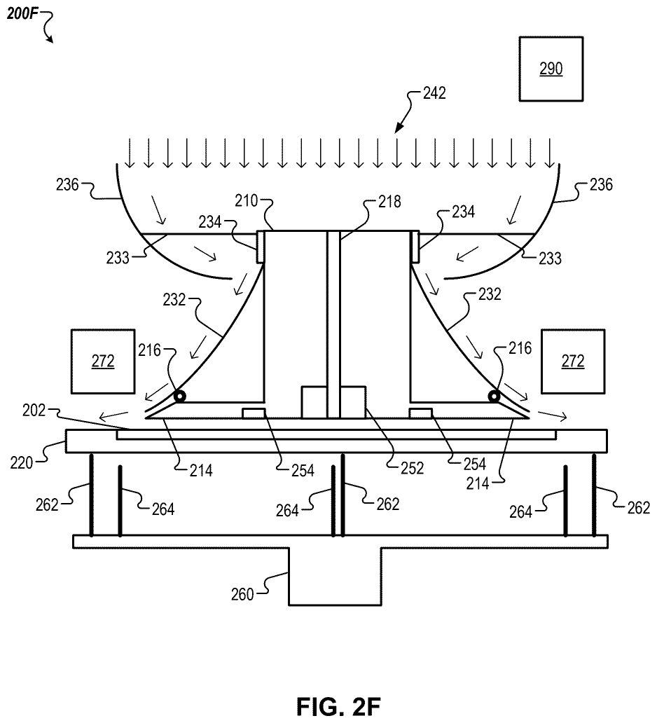

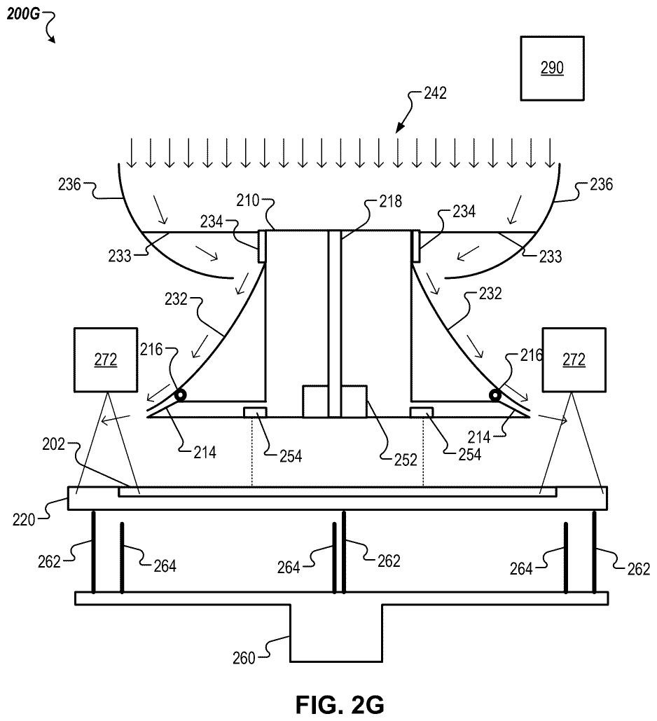

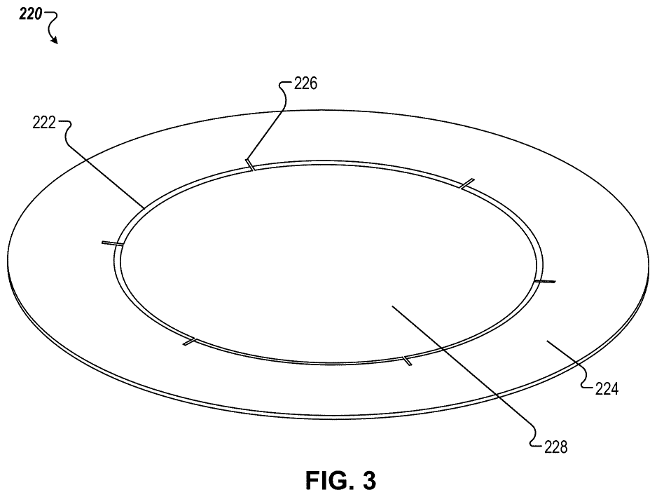

FIG. 2A-2G illustrate example schematic views of an example assembly station including a substrate gripper, in accordance with some embodiments of the present disclosure. Referring to FIG. 2A, a schematic view 200A of an example assembly station is shown. In some embodiments, a substrate gripper of the assembly station includes a body 210. The body 210 may have a substantially cylindrical shape. A bowl-shaped collector 236 may be coupled with the body 210 e.g., by multiple spokes 233. The spokes 233 may extend from a hub, such as collar 234. The bowl-shaped collector 236 may collect a flow of air 242 and may funnel the air 242 toward a central hole formed in the collector 236. In some embodiments, the air 242 includes clean dry air (CDA) and/or one or more inert gasses (e.g., such as helium and/or argon), etc. The air 242 may be received from one or more filters (e.g., of an equipment front-end module, of a factory interface, etc.). The air 242 collected in the bowl-shaped collector 236 may be downward flowing. In some embodiments, a laminar flow (e.g., substantially laminar flow) of air is provided into the bowl-shaped collector 236. In some embodiments, the bowl-shaped collector has an outer diameter between approximately 200 millimeters and approximately 300 millimeters. In some embodiments, the bowl-shaped collector has an outer diameter between approximately 250 millimeters and approximately 260 millimeters. In some embodiments, the central hole formed in the collector 236 has a diameter between approximately 100 millimeters and approximately 200 millimeters. In some embodiments, the central hole formed in the collector 236 has a diameter between approximately 140 millimeters and approximately 150 millimeters.

The substrate gripper may include a fairing to direct the flow of air 242 toward the edges of the substrate gripper and/or toward the edges of the substrate 202. In some embodiments, a bell-shaped flow cone 232 is coupled with the body 210. A collar 234 may be coupled with the body 210 and may push downward on the bell-shaped flow cone 232, securing the bell-shaped flow cone 232 to the body 210. In some embodiments, the collar 234 forms female threads that mate with male threads formed on the body 210. The periphery of the bell-shaped flow cone 232 may abut a beveled edge 214 of the body 210. In some embodiments, the bell-shaped flow cone 232 compresses an o-ring 216 that surrounds the body 210. The o-ring 216 may be proximate the beveled edge 214. In some embodiments, the flow cone contacts the o-ring 216, and does not contact the base of the gripper body.

The substrate 202 may be placed (e.g., by a robot, such as a factory interface robot) on lift pins 264 of lift assembly 260. In some embodiments, image sensors 272 capture image data indicative of the position of the substrate 202. For example, the image sensors 272 may capture image data (e.g., images) indicative of the position of the edge(s) of the substrate 202. In some embodiments, the assembly station includes three image sensors 272 disposed radially about a center axis of the substrate gripper at a position above the edge(s) of the substrate 202. Each of the image sensors 272 may be positioned to capture one or more images of a respective edge of the substrate 202. In some embodiments, included are three imaging devices (e.g., image sensors). The controller 290 may receive the image data from the image sensors 272. Using the received image data, the controller 290 may determine the position of the center of the substrate 202. The substrate center may be offset from a target position for the substrate. In some embodiments, the controller 290 determines the offset of the center of the substrate with respect to the target position for the substrate. The controller 290 may cause the robot to re-place the substrate on the lift pins 264 to correct for the offset. For example, the controller 290 may cause the robot to adjust the position of the substrate center to an adjusted position. The adjusted position may correspond to the target position for the substrate. In some embodiments, the controller 290 may cause the robot to adjust the position of the substrate center “on the fly” as image data is received. Placement of the substrate may thus be controlled as the substrate is delivered to the assembly station 260. In some embodiments, when the substrate 202 is correctly placed on the lift pins 264 (e.g., at the adjusted position), the lift assembly 260 may lift the substrate 202 to the bottom of the substrate gripper. In some embodiments, the lift assembly 260 may include a platform movable in the XYZ directions. In some embodiments, lift pins project upwards from the platform. Lift pins 264 may be for supporting a substrate and lift pins 262 may be for supporting a substrate support. In some embodiments, the lift assembly is configured to individually and collectively lift the substrate 202 and the susceptor 220 as explained herein.

The substrate gripper may include one or more proximity sensors 254. In some embodiments, the substrate gripper includes three proximity sensors 254. The proximity sensors 254 may be disposed in the gripper body 210 proximate the bottom surface of the gripper. In some embodiments, the proximity sensors 254 can detect an object beneath the gripper. Data from the sensors 254 can be used to determine the distance the object is away from the bottom of the gripper. For example, sensor data from one or more of the proximity sensors 254 can be used to determine how far away a substrate and/or a substrate support is from the bottom of the substrate gripper. The determined distance can be used to control the raising of the substrate and/or the substrate support to the gripper. Additionally, data from the sensors 254 can be used to determine whether a substrate is properly placed in the pocket of a substrate support. If the substrate is not properly placed in the pocket of a substrate support, one sensor 254 may indicate the substrate is closer than indicated by the other sensors. Corrective action may be performed accordingly.

In some embodiments, the proximity sensors 254 are reflective sensors (e.g., utilizing reflectometry, etc.). The proximity sensors 254 may emit a beam downward from the bottom of the substrate gripper toward an object below the gripper. For example, the proximity sensors 254 may emit beams downward toward the top surface of the substrate 202. At least a portion of the emitted beams may reflect off of the top surface of the substrate 202 and may travel back to the proximity sensors 254. The proximity sensors 254 may capture the reflected portion of the beam(s). The controller 290 may receive sensor data from the proximity sensors 254. The sensor data may be indicative of the distance between the proximity sensors 254 (e.g., the bottom of the substrate gripper) and the top surface of the substrate 202. As the substrate 202 is lifted by the lift assembly 260, the controller 290 may determine that the distance between the bottom of the substrate gripper and the substrate 202 gets smaller.

The controller 290 may be capable of determining the warpage of the substrate 202 based on data received from the proximity sensors 254. In some embodiments, the controller 290 compares distances between different portions of the top surface of the substrate 202 (e.g., indicated by sensor data received from the proximity sensors 254). A first portion of the top surface of the substrate 202 may be closer to an associated proximity sensor 254 than a second portion of the top surface of the substrate associated with another proximity sensor 254. The difference in distances may be caused by warpage of the substrate 202. In some embodiments, the substrate gripper and/or the processing system is capable of handling substrates having less than a threshold amount of warpage. Responsive to determining the substrate 202 has more than a threshold amount of warpage, the controller 290 may cause a robot (e.g., a factory interface robot) to remove the substrate 202 from the lift pins 264. The substrate may be taken away for scrapping. Responsive to determining the substrate 202 has less than a threshold amount of warpage, the controller 290 may cause the substrate 202 to be lifted (e.g., by the lift assembly 260) for gripping by the substrate gripper.

Referring to FIG. 2B, a schematic view 200B of an example assembly station is shown. When the distance between the bottom of the gripper and the top surface of the substrate 202 is less than a threshold distance (e.g., as determined by the controller 290), the controller 290 causes the lift assembly 260 to stop lifting the substrate 202. The controller 290 may cause the lift assembly 260 to hold the substrate 202 at the distance (e.g., the threshold distance) from the bottom of the gripper. A vacuum source (not illustrated) may be activated when the substrate 202 is disposed near the bottom of the substrate gripper (e.g., within the threshold distance of the bottom of the substrate gripper). Air (e.g., CDA, inert gas, etc.) may flow through vacuum tube 218 when the vacuum source is activated. Vacuum may be created beneath the substrate gripper, pulling the substrate 202 towards the gripper. However, the substrate 202 may be repelled from the bottom of the substrate gripper by ultrasonic vibration emitted from the sonotrode 252 as described herein below. In some embodiments, the sonotrode 252 emits ultrasonic vibrations that repels the substrate 202 away from the bottom of the gripper so that the top surface of the substrate 202 does not contact the bottom of the gripper. The pushing force generated by the ultrasonic vibrations may be counteracted by the vacuum force generated by the flow into the vacuum tube 218. In some embodiments, the sonotrode 252 at least partially protrudes from the bottom of the gripper body 210. The sonotrode 252 may protrude from the bottom of the gripper body 210 at least 0.45 millimeters. In some embodiments, the sonotrode 252 protrudes from the bottom of the gripper body 210 approximately 0.50 millimeters. In some embodiments, data from the proximity sensors 254 is used (by the controller 290) to verify the substrate 202 has not contacted the sonotrode 252. For example, the controller 290 may determine that the top surface of the substrate 202 is further away from the bottom of the gripper body 210 than the distance which the sonotrode 252 protrudes.

In some embodiments, a portion of air flowing down the bell-shaped flow cone 232 may be sucked into the space between the substrate 202 and the bottom of the gripper. The remaining portion of air flowing down the bell-shaped cone 232 may continue flowing radially away from the substrate 202 and may carry any particles away from the substrate 202. The portion of air sucked into the space between the substrate 202 and the bottom of the gripper may make a sharp U-turn around the edge of the bell-shaped flow cone 232, flow towards the center of the body 210 (e.g., between the substrate 202 and the gripper), and into the vacuum tube 218. The o-ring 216 may seal the space between the bell-shaped flow cone 232 and the gripper edge so that the flow of air does not go into the space inside the bell-shaped flow cone 232.

Referring to FIG. 2C, a schematic view 200C of an example assembly station is shown. The lift assembly 260 may be lowered away from the gripper. Because of the vacuum provided by the gripper, the substrate 202 may be retained (e.g., supported) by the gripper. A portion of the flow of air diverts from the flow of air down flowing down flow cone 232 and enters the space between the substrate 202 and the bottom of the gripper body. The diverted air is sucked through vacuum tube 218. Accordingly, the substrate 202 may be suspended beneath the substrate gripper without contacting the gripper.

Referring to FIG. 2D, a schematic view 200D of an example assembly station is shown. A susceptor 220 (e.g., a substrate support) may be placed (e.g., by a robot, such as a factory interface robot) on lift pins 262 of lift assembly 260. In some embodiments, image sensors 272 capture image data indicate of the position of the susceptor 220. For example, the image sensors 272 may capture image data (e.g., images) indicative of the position of the edge(s) of the susceptor 220. The controller 290 may receive the image data from the image sensors 272. Using the received image data, the controller may determine the position of the center of the susceptor 220. The substrate support center may be offset from a target position for the susceptor 220. The target position for the susceptor 220 may correspond to the position of the substrate 202. In some embodiments, the controller 290 determines the offset of the center of the susceptor 220 with respect to the target position for the susceptor 220. The controller 290 may cause the robot to re-place the susceptor 220 on the lift pins 262 to correct for the offset. For example, the controller 290 may cause the robot to adjust the position of the substrate support center to an adjusted position. The adjusted position may correspond to the target position for the susceptor 220 and/or to the position of the center of the substrate 202. In some embodiments, the controller 290 may cause the robot to adjust the position of the substrate support center “on the fly” as image data is received. Placement of the substrate support may thus be controlled as the substrate support is delivered to the assembly station 260. In some embodiments, when the susceptor 220 is correctly placed on the lift pins 262 (e.g., at the adjusted position), the lift assembly 260 may lift the susceptor 220 to the substrate 202 (e.g., supported by the gripper).

In some embodiments, the proximity sensors 254 can detect the presence of the susceptor 220 beneath the gripper and/or beneath the substrate 202. The substrate 202 may be at least partially transparent to the beam(s) emitted by the proximity sensors 254. Data from the sensors 254 can be used to determine how far away the susceptor 220 is from the bottom of the substrate 202. Based on data received from the proximity sensors 254, the controller 290 may be capable of determining whether just the substrate 202 is disposed beneath the gripper, whether the susceptor 220 is disposed beneath the substrate 202 beneath the gripper, and/or whether the substrate 202 is disposed on the susceptor 220 beneath the gripper. At least a portion of the beam(s) emitted by the sensors 254 may pass through the substrate 202 and may reflect off of the top surface of the susceptor 220. The reflected portion may travel back to the proximity sensors 254 (e.g., through the substrate 202). The proximity sensors 254 may capture the reflected portions of the beam(s). The controller 290 may receive sensor data from the proximity sensors 254 indicative of the distance between the proximity sensors 254 (e.g., the bottom of the substrate gripper) and the top surface of the susceptor 220. The controller 290 may determine the distance between the top surface of the susceptor 220 and the bottom surface of the substrate 202 based on the sensor data, the position of the substrate 202, and/or the thickness of the substrate 202, etc. As the susceptor 220 is lifted by the lift assembly 260, the controller 290 may determine that the distance between the bottom of the substrate 202 and the susceptor 220 gets smaller.

Referring to FIG. 2E, a schematic view 200E of an example assembly station is shown. When the distance between the susceptor 220 and the bottom of the substrate 202 is less than a threshold distance (e.g., as determined by the controller 290), the controller 290 causes the lift assembly 260 to stop lifting the susceptor 220. The controller 290 may cause the lift assembly 260 to hold the substrate support at the distance (e.g., the threshold distance) from the bottom of the substrate 202. In some embodiments, the image sensors 272 collect image data indicative of the position of the substrate 202 with respect to the pocket of the susceptor 220. If the controller 290 determines the edge(s) of the substrate 202 are aligned with the edge(s) of the pocket of the susceptor 220, the controller 290 may initiate placement of the substrate 202 onto the susceptor 220. If the controller 290 determines the edge(s) of the substrate 202 are not aligned with the edge(s) of the pocket of the susceptor 220, the controller 290 may initiate realignment of the susceptor 220. Realignment of the susceptor 220 may include lowering the susceptor 220 (e.g., by lift assembly 260) and re-placement of the susceptor 220 on the lift pins 262 (e.g., by a robot). The re-placed susceptor 220 may again be lifted to the substrate 202.

The flow of air down the sides of the bell-shaped flow cone 232 may radiate outwards from the bell-shaped flow cone 232 and may carry any particles on the edges of the substrate 202 and/or on the edges of the susceptor 220 away from the substrate 202.

Referring to FIG. 2F, a schematic view 200F of an example assembly station is shown. Responsive to the controller 290 determining the substrate 202 is properly aligned with the pocket of the susceptor 220, the vacuum source of the substrate gripper may be deactivated. Deactivation of the vacuum source may cause the substrate 202 to be placed (e.g., dropped) onto the susceptor 220 (e.g., into the pocket of the susceptor 220). Placing (e.g., dropping) of the substrate 202 onto the susceptor 220 may constitute assembling the substrate 202 to the susceptor 220. Once the substrate 202 is assembled to the substrate support (e.g., placed on the susceptor 220), the susceptor 220 supporting the substrate 202 may be lowered by the lift assembly 260.

Referring to FIG. 2G, a schematic view 200G of an example assembly station is shown. In some embodiments, the susceptor 220 supporting the substrate 202 is sufficiently lowered so that the susceptor 220 supporting the substrate 202 can be retrieved by a robot (e.g., a factory interface robot). In some embodiments, the image sensors 272 collect image data indicative of the edge of the substrate 202. The controller 290 may receive the image data and may use the image data to determine whether the substrate 202 is properly seated in the pocket of the susceptor 220. In some embodiments, the proximity sensors 254 collect sensor data indicative of the distance of the top surface of the substrate 202 from the bottom of the substrate gripper. The controller 290 may receive the sensor data and may use the sensor data to determine whether the substrate 202 is properly seated in the pocket of the susceptor 220. If one sensor 254 collects sensor data indicating the top surface of the substrate 202 is closer to the bottom of the substrate gripper than another one of the sensors 254 (e.g., that the substrate 202 is canted at an angle), the controller 290 may determine the substrate is not properly seated in the pocket. The controller 290 may then initiate re-placement of the substrate 202 on the susceptor 220 (e.g., by re-gripping the substrate 202 and re-placing the substrate 202 on the susceptor 220). In some embodiments, determining whether the substrate 202 is properly placed in the pocket of the susceptor 220 can be performed after the susceptor 220 supporting the substrate 202 has been lowered away from the substrate gripper or while the susceptor 220 is proximate the bottom of the substrate griper, such as after the substrate 202 has been placed on the susceptor 220 (e.g., as in FIG. 2F). Responsive to determining the substrate 202 is properly placed in the pocket of the susceptor 220, the controller 290 may cause the susceptor 220 supporting the substrate 202 to be transported away from the assembly station. The susceptor 220 supporting the substrate 202 may be transported (e.g., by a robot) into a load lock (e.g., a degassing chamber, such as degassing chamber 104 of FIG. 1A). The susceptor 220 supporting the substrate 202 may then be transported into one or more process chamber (e.g., via a transfer chamber, etc.) for processing of the substrate 202.

FIG. 3 illustrates a simplified perspective view of a susceptor 220, in accordance with some embodiments of the present disclosure. In some embodiments, the susceptor 220 forms a pocket 228. The pocket 228 may be a recess surrounded by a rim 224. A shelf 222 may extend circumferentially around the pocket 228. The shelf 222 may be disposed within the pocket 228 proximate a circumferential edge of the pocket 228. In some embodiments, a substrate (not illustrated in FIG. 3) may be disposed within the pocket 228, supported on the shelf 222. When a substrate is disposed within the pocket 228, the top surface of the substrate may be substantially flush with the top surface of rim 224. In some embodiments, rim 224 forms channels 226. The channels 226 may extend through the shelf 222. In some embodiments, the channels 226 have a width less than approximately one millimeter. In some embodiments, shelf 222 and/or channels 226 are not present.

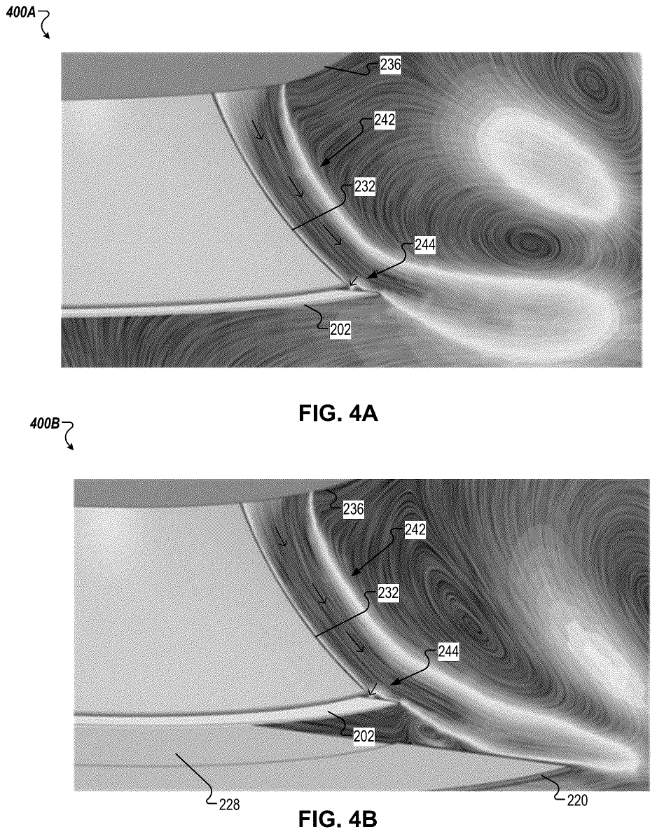

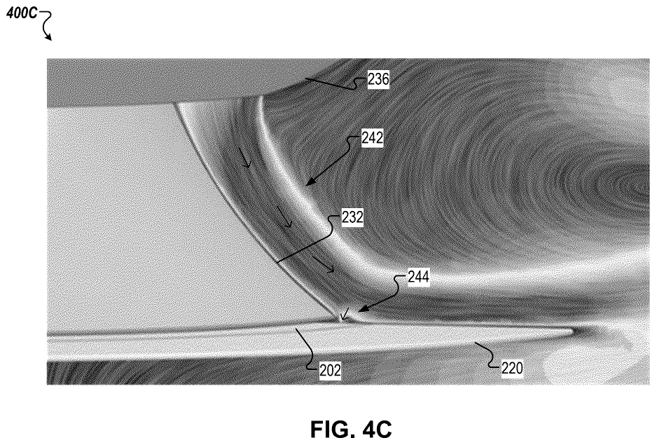

FIGS. 4A-C illustrate depictions of air flow 242 proximate to a substrate gripper, in accordance with some embodiments of the present disclosure. Referring to FIG. 4A, a depiction 400A is shown. A substrate 202 may be supported by a substrate gripper. The air flow 242 may flow from a bowl-shaped collector 236 down the sides of a bell-shaped flow cone 232. In some embodiments, a portion of the air 244 diverts (e.g., diverges) from the main flow of air 242 at the edge of the bell-shaped flow cone 232 and may flow between the substrate 202 and the bottom of the substrate gripper. The portion of the air 244 may be sucked away from the main flow of air 242 by vacuum generated to support the substrate 202. In some embodiments, the portion of the air 244 is diverted from the main flow of air 242 within the outer radius of the substrate 202. The portion of the air 244 may curve around the edge of the bell-shaped flow cone 232 without flowing pas the outer radius (e.g., the outer edge, etc.) of the substrate 202. Referring to FIG. 4B, a depiction 400B is shown. A susceptor 220 may be lifted toward the substrate gripper and the substrate 202 (e.g., by a lift assembly, etc.). Particles may be on the top surface of the susceptor 220. The portion of the air 244 diverts from the main flow of air 242 within the substrate 202 radius to ensure no particles or contamination from the susceptor 220 surface are presented to the substrate 202 surface during the gripping operation. The air flow 242 may flow radially from the edges of the bell-shaped flow cone 232 and may carry any particles on the edges of the substrate 202 and/or on the susceptor 220 away from the top surface of the substrate 202. In some embodiments, the susceptor 220 is raised so that the substrate 202 fits into the pocket 228. Referring to FIG. 4C, a depiction 400C is shown. The susceptor 220 may be lifted so that the substrate 202 fits into the pocket formed into the susceptor 220. The vacuum generated to support the substrate 202 may be deactivated which may allow the substrate 202 to be completely supported by the susceptor 220.

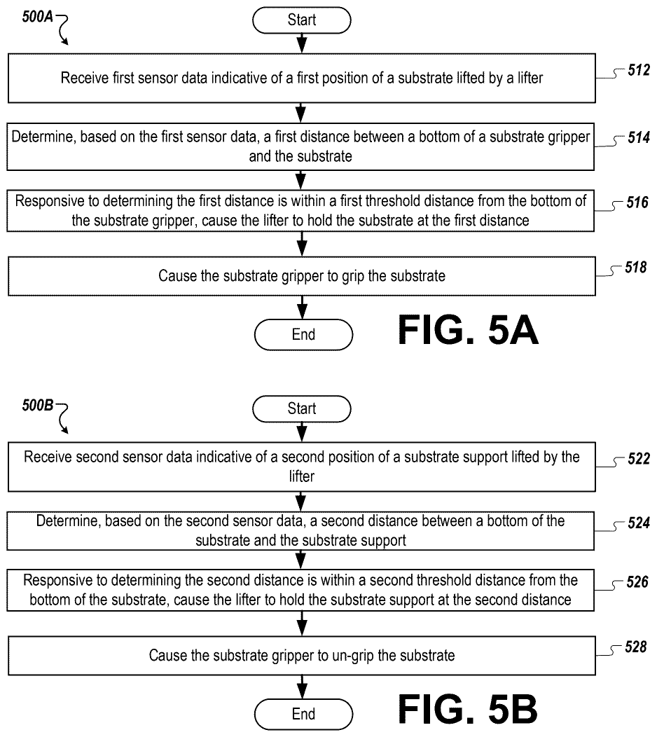

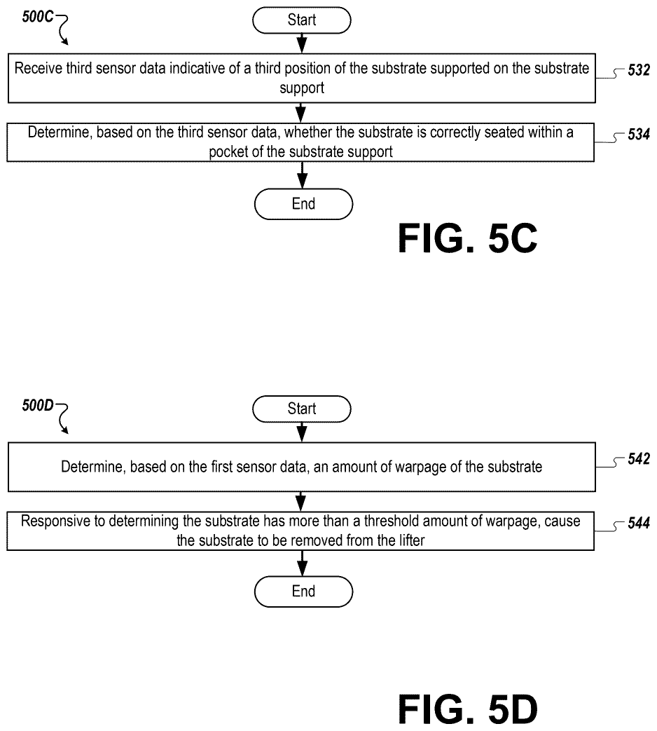

FIGS. 5A-D are flow diagrams of example methods for controlling a substrate gripper using proximity sensors, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 5A, a flow diagram for a method 500A is shown. At block 512, first sensor data is received. In some embodiments, the first sensor data is indicative of a first position of a substrate lifted by a lifter (e.g., a lift assembly). In some embodiments, a controller receives the first sensor data from one or more proximity sensors. The proximity sensor(s) may be disposed in the base of a substrate gripper. In some embodiments, the proximity sensor(s) measure a distance between the sensor(s) and the top surface of a substrate positioned on a lifter. In some embodiments, the proximity sensor(s) are reflective sensor(s). For example, the one or more proximity sensors may each emit a beam toward the surface of the substrate. The substrate may be at least partially transparent to the one or more proximity sensors (e.g., to the beam(s) emitted by the one or more proximity sensors). A portion of the beam may be reflected off of the surface of the substrate back toward the sensor(s). The sensor(s) may measure the portion of the reflected beam (e.g., the intensity or one or more other parameters, etc. of the reflected portion of the beam).

At block 514, the controller determines, based on the first sensor data, a first distance between a bottom of a substrate gripper and the substrate. Using the first sensor data (e.g., received at block 512), the controller may determine how far the top surface of the substrate is from the bottom of the substrate gripper. In some embodiments, the controller retrieves the first distance from a look-up table. The look-up table may include sensor data values corresponding to associated distance values. To avoid contacting the substrate with the bottom of the substrate gripper, the controller may cause the lifter (e.g., the lift assembly) to stop lifting the substrate when the substrate comes within a first threshold distance of the bottom of the substrate gripper.

At block 516, responsive to determining the first distance (e.g., determined at block 514) is within a first threshold distance from the bottom of the substrate gripper, the controller may cause the lifter to hold the substrate at the first distance. In some embodiments, when the substrate is within the first threshold distance from the bottom of the substrate gripper, to avoid contacting the top surface of the substrate with the bottom of the substrate gripper, the controller causes the lifter to stop lifting the substrate. The controller may cause the lifter to hold the substrate at the first position. The first position may be within a threshold distance that the substrate gripper can grip the substrate.

At block 518, the controller causes the substrate gripper to grip the substrate. In some embodiments, a vacuum source coupled with the substrate gripper is activated to induce a vacuum between the top surface of the substrate and the bottom surface of the substrate gripper. The induced vacuum may cause the substrate to be supported by the substrate gripper. In some embodiments, a sonotrode in the substrate gripper is activated to emit ultrasonic vibrations that repel the substrate from the bottom of the substrate gripper. The emitted ultrasonic vibrations may at least partially counteract the induced vacuum so that the substrate is supported by the substrate gripper by vacuum without contacting the bottom of the substrate gripper. Subsequent to gripping of the substrate by the substrate gripper, the lifter may lower away from the gripped substrate.

Referring to FIG. 5B, a flow diagram for a method 500B is shown. Method 500B may be performed in conjunction with method 500A. At block 522, second sensor data is received. In some embodiments, the second sensor data is indicative of a second position of a substrate support (e.g., a susceptor) lifted by the lifter. In some embodiments, the second sensor data is received by the controller from the one or more proximity sensors (e.g., of method 500A). In some embodiments, the substrate support is lifted beneath the substrate supported by the substrate gripper. Because the substrate may be at least partially transparent to the one or more proximity sensors, the beam(s) emitted by the sensor(s) may at least partially travel through the supported substrate to the substrate support. A portion of the beam(s) may reflect off of the substrate support and travel back to the proximity sensor(s).

At block 524, the controller determines, based on the second sensor data (e.g., received at block 524), a second distance between a bottom of the substrate and the substrate support. In some embodiments, the controller determines the distance from the substrate gripper to the substrate support using a look-up table that includes sensor data values corresponding to associated distance values. The controller may use the distance from the substrate to the substrate gripper when determining the distance from the substrate support to the substrate. For example, the controller may subtract the distance from the substrate to the substrate gripper from the distance from the substrate support to the substrate gripper to determine the distance from the substrate gripper to the substrate.

At block 526, responsive to determining the second distance (e.g., determined at block 524) is within a second threshold distance from the bottom of the substrate, the controller may cause the lifter to hold the substrate support at the second distance. In some embodiments, when the substrate support is within the second threshold distance from the bottom of the substrate, to avoid harmfully contacting the bottom of the substrate with the substrate support, the controller causes the lifter to stop lifting the substrate. The controller may cause the lifter to hold the substrate support at the second position. The second position may be within a threshold distance the substrate can fall (e.g., after being ungripped by the substrate gripper) onto the substrate support without damage to the substrate and/or to the substrate support.

At block 528, the controller causes the substrate gripper to un-grip the substrate. In some embodiments, the vacuum source coupled with the substrate gripper is de-activated to stop the vacuum between the top surface of the substrate and the bottom surface of the substrate gripper. The substrate may then be unsupported by the substrate gripper and may fall onto the substrate support. In some embodiments, the substrate falls into a pocket of the substrate support. Subsequent to un-gripping of the substrate by the substrate gripper, the substrate may be supported by the substrate support. The lifter may lower the substrate support (e.g., supporting the substrate) away from the substrate gripper.

Referring to FIG. 5C, a flow diagram for a method 500C is shown. Method 500C may be performed in conjunction with method 500A and/or method 500B. At block 532, third sensor data is received. The third sensor data may be indicative of a third position of the substrate supported on the substrate support. In some embodiments, the controller receives the third sensor data from the one or more proximity sensors. The third sensor data may indicate whether the substrate is tilted or flat, etc. on the substrate support.

At block 534, the controller determines, based on the third sensor data (e.g., received at block 532) whether the substrate is correctly seated within a pocket of the substrate support. The controller may use a look-up table including sensor data values corresponding to associated distance values. In some embodiments, the controller compares distance values determined from the sensor data received from the different sensors. For example, the controller may compare a first distance value indicated by sensor data from a first proximity sensor with a second distance value indicated by sensor data from a second proximity sensor and/or with a third distance value indicated by sensor data from a third proximity sensor. If any of the distance values have more than a threshold difference from any of the other distance values, the substrate may be tilted on the substrate support. Tilting of the substrate on the substrate support may mean the substrate is not properly seated in the pocket of the substrate support. For example, one edge of the substrate may be sitting on the rim of the substrate support and not (fully) in the pocket, causing the substrate to be tilted. Responsive to determining the substrate is not correctly seated within the pocket of the substrate support, the controller may cause the substrate to be re-gripped by the substrate gripper and re-placed on the substrate support. Responsive to determining the substrate is correctly seated within the pocket of the substrate support, the controller may cause the substrate to be processed.

Referring to FIG. 5D, a flow diagram of a method 500D is shown. Method 500D may be performed in conjunction with method 500A. At block 542, the controller determines, based on the first sensor data (e.g., received at block 512 of method 500A), an amount of warpage of the substrate. The controller may compare distance values indicated by first sensor data received from the different proximity sensors to determine warpage of the substrate. For example, the controller may compare a distance indicated by sensor data from a first proximity sensor with another distance indicated by sensor data from a second proximity sensor and/or another distance indicated by sensor data from a third proximity sensor, etc. Differences in the distances may correspond to warpage of the substrate. Where a distance between the top surface of a first portion of the substrate and the associated proximity sensor is less than the distance between the top surface of a second portion of the substrate and the associated proximity sensor, the substrate may be warped (e.g., at the first portion). The system may only be capable of handling substrates with less than a threshold amount of warpage.

At block 544, responsive to determining the substrate has more than a threshold amount of warpage, the controller may cause the substrate to be removed from the lifter. In some embodiments, the controller causes a robot (e.g., a factory interface robot) to retrieve the substrate from the lifter. The warped substrate may be scrapped. Responsive to determining the substrate has less than the threshold amount of warpage, the substrate may be gripped (e.g., by the substrate gripper) and placed on a substrate support (e.g., for processing).

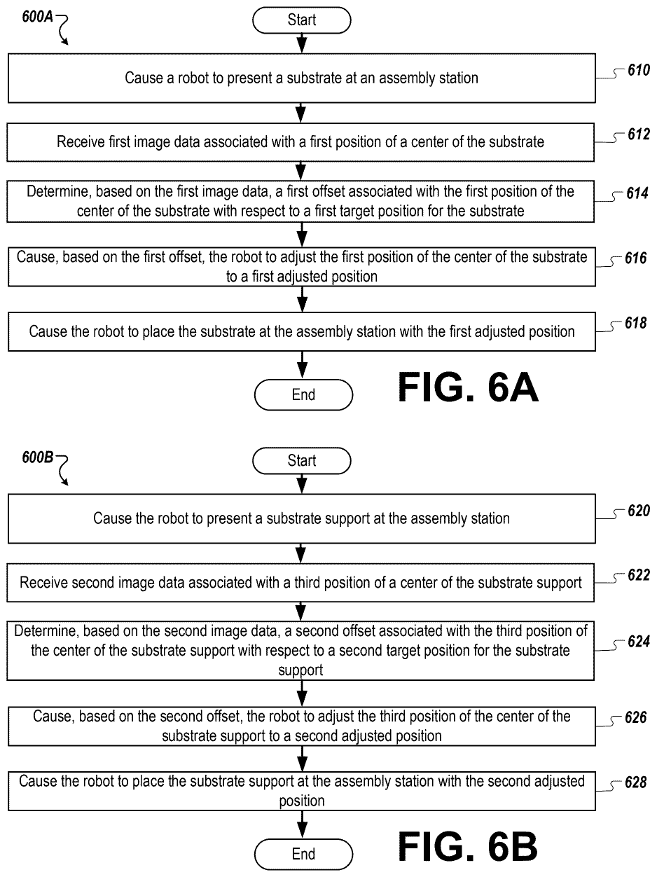

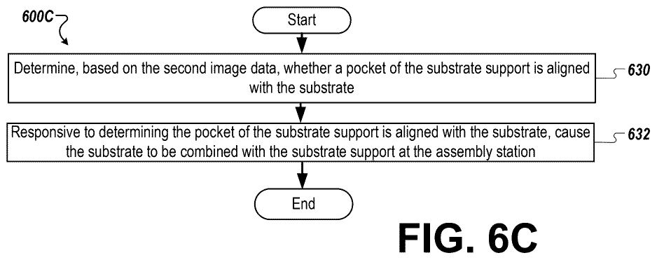

FIGS. 6A-C are flow diagrams of example methods for controlling the placement of a substrate at a substrate assembly station using image sensors, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 6A, a flow diagram for a method 600A is shown. At block 610, a robot is caused to present a substrate at an assembly station. In some embodiments, a controller causes a robot (e.g., a factory interface robot) to place a substrate on lift pin(s) of a lifter of the assembly station. The substrate may be retrieved (e.g., by the robot) from an enclosure, such as an enclosure coupled with a factory interface.

At block 612, first image data associated with a first position of a center of the substrate is received. The first image data may be indicative of one or more edges of the substrate presented at the assembly station. In some embodiments, the first image data is received from one or more (e.g., multiple) image sensors. The one or more image sensors may be disposed radially around the substrate and may be positioned to capture image data (e.g., images) of the edge(s) of the substrate. In some embodiments a controller receives the first image data from the image sensors. The controller may determine the first position of the center of the substrate based on the position of the edge(s) of the substrate (e.g., using the first image data).

At block 614, the controller determines, based on the first image data (e.g., received at block 612), a first offset associated with the first position of the center of the substrate with respect to a first target position for the substrate. The center of the substrate may be offset (e.g., by the first offset) from the target position for the substrate. Using the first image data, the controller may determine the magnitude and/or the direction of the first offset that the center of the substrate is offset with respect to the first target position for the substrate. The first target position for the substrate may correspond to a position for lifting and/or assembling the substrate to a substrate support at the assembly station.

At block 616, based on the first offset (e.g., determined at block 614), the robot is caused to adjust the first position of the center of the substrate to a first adjusted position. In some embodiments, the controller causes the robot to at least partially pick up the substrate at the assembly station and adjust the position of the substrate (e.g., move the substrate) to an adjusted position. The robot may move the substrate (e.g., adjust the position of the substrate) by the first offset (e.g., determined at block 614).

At block 618, the controller causes the robot to place the substrate at the assembly station with the first adjusted position. The first adjusted position may correspond to the first target position for the substrate. In some embodiments, the controller causes the substrate to be lifted (e.g., by the lifter) for gripping by a substrate gripper of the assembly station. The substrate may then be assembled to the substrate support.

Referring to FIG. 6B, a flow diagram for a method 600B is shown. Method 600B may be performed in conjunction with method 600A. At block 620, the robot is caused to present a substrate support (e.g., a susceptor) at the assembly station. In some embodiments, the robot retrieves the substrate support from a storage station (e.g., of a factory interface). In some embodiments, the controller causes the robot to place the substrate on lift pin(s) of the lifter of the assembly station.

At block 622, second image data associated with a third position of a center of the substrate support is received. The second image data may be indicative of one or more edges of the substrate support presented at the assembly station. In some embodiments, the second image data is received from the one or more image sensors. In some embodiments, the controller receives the second image data from the image sensors. The controller may determine the third position of the center of the substrate support based on the position of the edge(s) of the substrate support (e.g., using the second image data).

At block 624, the controller determines, based on the second image data (e.g., received at block 622), a second offset associated with the third position of the center of the substrate support with respect to a second target position for the substrate support. The center of the substrate support may be offset (e.g., by the second offset) from the target position for the substrate support. Using the second image data, the controller may determine the magnitude and/or the direction of the second offset that the center of the substrate support is offset with respect to the second target position for the substrate support. The second target position for the substrate support may be with respect to the substrate. The second target position for the substrate support may correspond to a position for lifting and/or assembling the substrate to the substrate support at the assembly station. In some embodiments, determining the second offset includes determining the difference between the first adjusted position of the substrate (e.g., associated with block 616 of method 600A) and the third position of the center of the substrate support (e.g., associated with block 622).

At block 626, based on the second offset (e.g., determined at block 624), the robot is caused to adjust the third position of the center of the substrate support to a second adjusted position. In some embodiments, the controller causes the robot to at least partially pick up the substrate support at the assembly station and adjust the position of the substrate support (e.g., move the substrate support) to an adjusted position. The robot may move the substrate support (e.g., adjust the position of the substrate support) by the second offset (e.g., determined at block 624).

At block 628, the controller causes the robot to place the substrate support at the assembly station with the second adjusted position. The second adjusted position may correspond to the second target position for the substrate support. In some embodiments, the controller causes the substrate support to be lifted (e.g., by the lifter) for assembling the substrate to the substrate support.

Referring to FIG. 6C, a flow diagram for a method 600C is shown. Method 600C may be performed in conjunction with method 600A and/or method 600B. At block 630, the controller determines, based on the second image data (e.g., received at block 622 of method 600B) whether a pocket of the substrate support is aligned with the substrate. In some embodiments, the controller determines whether the edges of the substrate are aligned with the edges of the pocket of the substrate support using the second image data.

At block 632, responsive to determining the pocket of the substrate is aligned with the substrate, the controller causes the substrate to be combined with (e.g., assembled to) the substrate support at the assembly station. In some embodiments, after determining the pocket of the substrate support is aligned with the substrate, the controller causes the substrate support to be lifted toward the substrate and further causes the substrate to be placed on the substrate support within the pocket. In some embodiments, after determining the pocket of the substrate support is not aligned with the substrate, the controller causes the robot to move the substrate support into alignment with the substrate. Subsequently, the substrate can be assembled to the substrate support (e.g., placed on the substrate support).

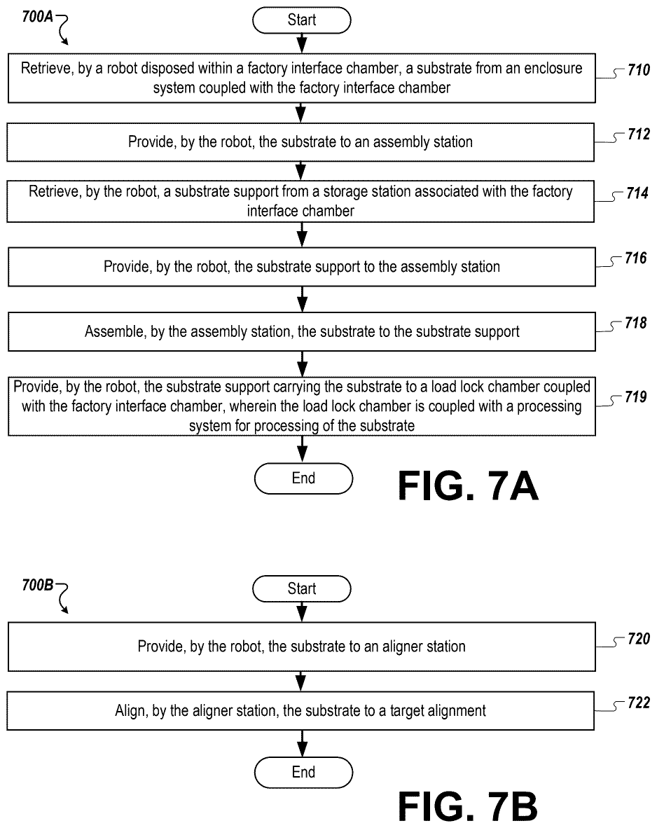

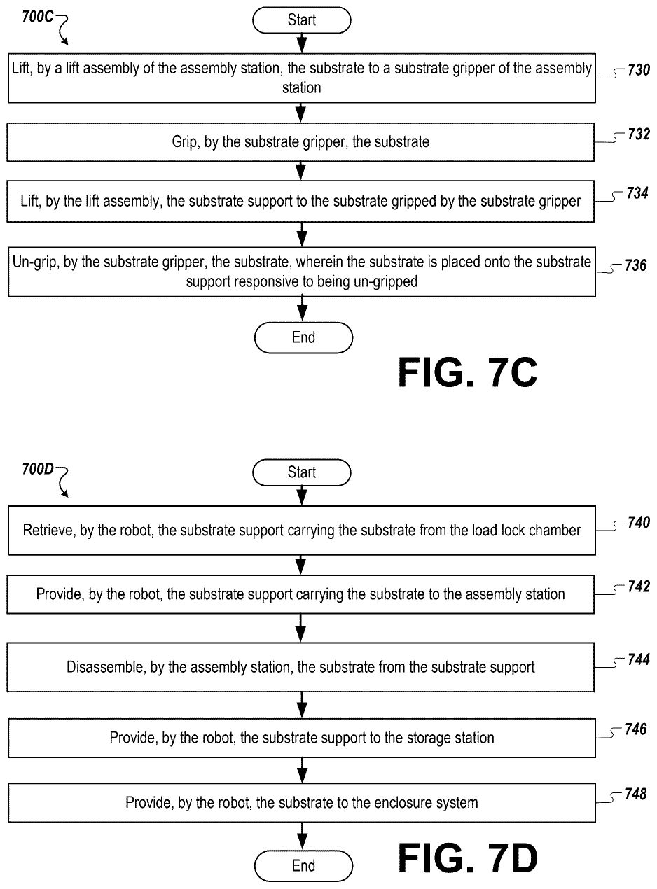

FIGS. 7A-D are flow diagrams of example methods for assembling a substrate to a substrate support, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 7A, a flow diagram for a method 700A is shown. At block 710, a substrate is retrieved by a robot disposed within a factory interface chamber from an enclosure system coupled with the factory interface chamber. The enclosure system may be docked with the factory interface (e.g., at a load port).

At block 712, the substrate is provided, by the robot, to an assembly station. The assembly station may be associated with the factory interface. In some embodiments, the assembly station is disposed within the factory interface chamber. The assembly station may include a lifter (e.g., a lift assembly) and/or a substrate gripper for assembling the substrate to a substrate support (e.g., for placing the substrate on a substrate support). In some embodiments, the substrate is placed, by the robot, on one or more lift pins of the lifter.

At block 714, a substrate support is retrieved, by the robot, from a storage station associated with the factory interface chamber. In some embodiments, the storage station is disposed within the factory interface chamber. The storage station may include multiple shelves for storing multiple substrate supports and/or multiple substrates.

At block 716, the substrate support is provided, by the robot, to the assembly station. In some embodiments, the substrate is placed, by the robot, one or more lift pins of the lifter.

At block 718, the substrate is assembled, by the assembly station, to the substrate support. After the substrate is provided to the assembly station (e.g., at block 712), the substrate is lifted (e.g., by the lifter) to a substrate gripper. The substrate gripper may grip the substrate to support the substrate. The lifter may then be lowered and the substrate support provided to the assembly station (e.g., at block 716). The substrate support may then be lifted to the substrate and the substrate placed on the substrate support. The substrate support may then support the substrate.

At block 719, the substrate support carrying the substrate is provided, by the robot, to a load lock chamber (e.g., a degassing chamber) coupled with the factory interface chamber. The load lock chamber may be coupled with a processing system for processing of the substrate. In some embodiments, the robot retrieves the assembled substrate and substrate support (e.g., the substrate carried on the substrate support) from the assembly station. The robot may provide the assembled substrate and substrate support to the load lock. After processing of the substrate, the robot may retrieve the assembled substrate and substrate support from the load lock and provide the assembled substrate and substrate support to the assembly station for disassembly of the substrate from the substrate support. The robot may place the substrate support in the storage station and may place the processed substrate in an enclosure system coupled with the factory interface chamber.

Referring to FIG. 7B, a flow diagram for a method 700B is shown. Method 700B may be performed in conjunction with method 700A. At block 720, the substrate is provided, by the robot, to an aligner station. In some embodiments, the aligner station is disposed within the factory interface chamber. The aligner station may be disposed coaxially with the assembly station. For example, an aligner station of the aligner station may be disposed coaxial with the lift stage of the assembly station. Disposing the aligner station coaxially with the assembly station may allow for the thermal expansion of the robot to be accounted for only once for hand-offs at the aligner station and at the assembly station. In some embodiments, the aligner station is disposed beneath the assembly station.

At block 722, the substrate is aligned to a target alignment by the aligner station. In some embodiments, the aligner stage of the aligner station rotates to rotate the substrate to the target alignment. Alignment of the substrate may be performed based on a reference feature (e.g., a notch) of the substrate.

Referring to FIG. 7C, a flow diagram for a method 700C is shown. Method 700C may be performed in conjunction with method 700A. At block 730, the substrate is lifted, by a lift assembly of the assembly station, to a substrate gripper of the assembly station. In some embodiments, one or more lift pins supporting the substrate are lifted to lift the substrate.

At block 732, the substrate is gripped by the substrate gripper. In some embodiments, the substrate is supported by vacuum induced by the substrate gripper. In some embodiments, the substrate is supported by one or more arms of the substrate gripper. The substrate may be supported by the substrate gripper so that the lift assembly can be lowered, such as to receive a substrate support (e.g., a susceptor).

At block 734, the substrate support is lifted, by the lift assembly, to the substrate gripped by the substrate gripper. In some embodiments, one or more lift pins supporting the substrate support are lifted to lift the substrate support. The one or more lift pins supporting the substrate may be different lift pins than the lift pins that supported the substrate at block 730.

At block 736, the substrate is un-gripped by the substrate gripper. The substrate may be un-gripped when the substrate support is within a threshold distance from the bottom of the substrate. In some embodiments, responsive to being un-gripped, the substrate falls onto the substrate support. The substrate may fall into a pocket of the substrate support.

Referring to FIG. 7D, a flow diagram for a method 700D is shown. Method 700D may be performed in conjunction with method 700A and/or method 700C. At block 740, the substrate support carrying the substrate is retrieved, by the robot, from the load lock chamber (e.g., degassing chamber). The substrate may have been processed, such as by a processing system coupled with the load lock chamber.

At block 742, the substrate support carrying the substrate is provided, by the robot, to the assembly station. In some embodiments, the robot places the substrate support carrying the substrate on one or more lift pins of the assembly station.

At block 744, the substrate is disassembled from the substrate support by the assembly station. In some embodiments, the substrate support carrying the substrate is lifted to the substrate gripper (e.g., by the lift assembly). The substrate gripper may grip the substrate. Once the substrate is gripped (by the substrate gripper), the substrate support is lowered away from the substrate and the substrate gripper.

At block 746, the substrate support is provided, by the robot, to the storage station. In some embodiments, the robot retrieves the substrate support from the assembly station and transports the substrate support to the storage station. The robot may place the substrate support on one or more shelves of the storage station for storage.

At block 748, the substrate is provided, by the robot, to the enclosure system (e.g., an enclosure system coupled with the factory interface chamber). In some embodiments, the substrate is un-gripped (e.g., by the substrate gripper) and lowered (e.g., by the lift assembly). In some embodiments, the robot retrieves the substrate from the assembly station and transports the substrate to the enclosure system. The enclosure system may be the same enclosure system as the substrate was originally retrieved from (e.g., at block 710), or may be a different enclosure system.

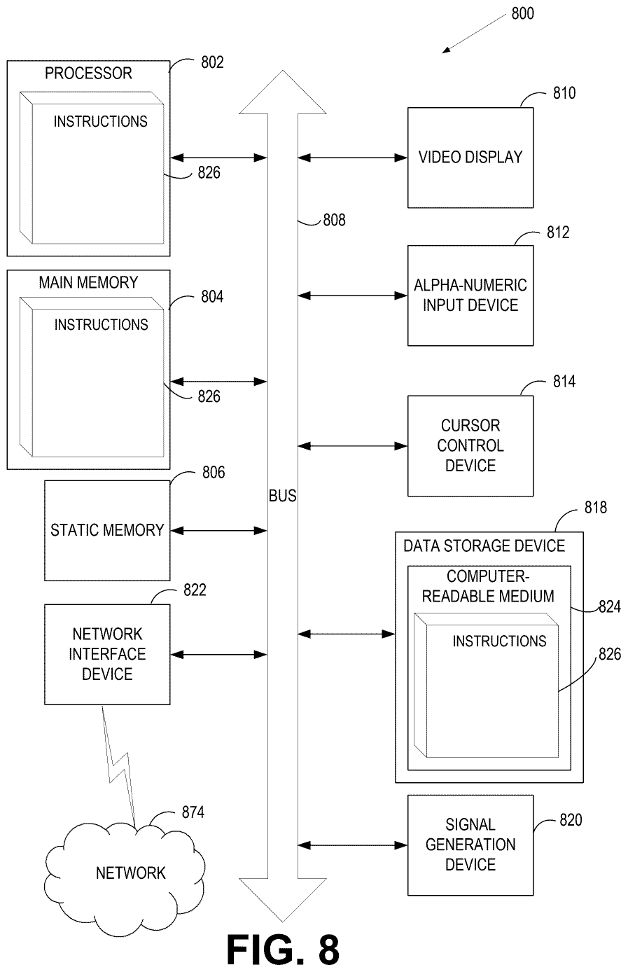

FIG. 8 is a block diagram illustrating a computer system 800, according to aspects of the present disclosure. In some embodiments, the computer system 800 is a controller device (e.g., server, controller 290, etc.).

In some embodiments, computer system 800 is connected (e.g., via a network, such as a Local Area Network (LAN), an intranet, an extranet, or the Internet) to other computer systems. Computer system 800 operates in the capacity of a server or a client computer in a client-server environment, or as a peer computer in a peer-to-peer or distributed network environment. In some embodiments, computer system 800 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In some embodiments, the computer system 800 includes a processor 802, a volatile memory 804 (e.g., Random Access Memory (RAM)), a non-volatile memory 806 (e.g., Read-Only Memory (ROM) or Electrically-Erasable Programmable ROM (EEPROM)), and/or a data storage device 816, which communicates with each other via a bus 808.

In some embodiments, processor 802 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor). In some embodiments, processor 802 is provided by one or more of a single processor, multiple processors, a single processor having multiple processing cores, and/or the like.

In some embodiments, computer system 800 further includes a network interface device 822 (e.g., coupled to network 874). In some embodiments, the computer system 800 includes one or more input/output (I/O) devices. In some embodiments, computer system 800 also includes a video display unit 810 (e.g., an LCD), an alphanumeric input device 812 (e.g., a keyboard), a cursor control device 814 (e.g., a mouse), and/or a signal generation device 820.

In some implementations, data storage device 818 (e.g., disk drive storage, fixed and/or removable storage devices, fixed disk drive, removable memory card, optical storage, network attached storage (NAS), and/or storage area-network (SAN)) includes a non-transitory computer-readable storage medium 824 on which stores instructions 826 encoding any one or more of the methods or functions described herein.

In some embodiments, instructions 826 also reside, completely or partially, within volatile memory 804 and/or within processor 802 during execution thereof by computer system 800, hence, volatile memory 804 and processor 802 also constitute machine-readable storage media, in some embodiments.

While computer-readable storage medium 824 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

It should be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplary language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

What is claimed is:

1. A substrate gripper, comprising:
a gripper body having a base configured to support a substrate by vacuum;
a bowl-shaped collector coupled with the gripper body and configured to collect a flow of air; and
a bell-shaped flow cone coupled with the gripper body and configured to direct the flow of air toward an edge of the gripper body.

2. The substrate gripper of claim 1, wherein the base of the gripper body comprises a beveled edge.

3. The substrate gripper of claim 1, further comprising:
a sonotrode configured to create ultrasonic vibrations that repels the substrate from the gripper body.

4. The substrate gripper of claim 1, wherein a portion of the flow of air is directed around the edge of the gripper body toward a vacuum port disposed in a bottom of the gripper body, and wherein the portion of the flow of air diverts from the flow of air within an outer radius of the substrate.

5. The substrate gripper of claim 1, wherein the gripper body comprises a substantially cylindrical shape, and wherein the bowl-shaped collector and the bell-shaped flow cone are disposed coaxial with the substantially cylindrical shape of the gripper body.

6. The substrate gripper of claim 1, wherein the bowl-shaped collector is coupled with the gripper body by multiple spokes coupled with a hub, wherein the hub is coupled to a top of the gripper body.

7. The substrate gripper of claim 1, further comprising an o-ring disposed between the bell-shaped flow cone and the gripper body, wherein the bell-shaped flow cone at least partially compresses the o-ring.

8. The substrate gripper of claim 1, further comprising:
one or more proximity sensors disposed within the gripper body, wherein the one or more proximity sensors are configured to sense a distance between a bottom of the base and an object disposed beneath the gripper body.

9. The substrate gripper of claim 8, wherein supporting of the substrate by vacuum is performed based on the distance between the bottom of the base and the object disposed beneath the gripper body.

10. A substrate gripper, comprising:
a gripper body having a base configured to support a substrate by vacuum; and
one or more proximity sensors disposed within the base of the gripper body, wherein the one or more proximity sensors are configured to sense a distance between a bottom of the base and an object disposed beneath the gripper body.

11. The substrate gripper of claim 10, further comprising:
a bowl-shaped collector coupled with the gripper body and configured to collect a flow of air; and
a bell-shaped flow cone coupled with the gripper body and configured to direct the flow of air toward an edge of the gripper body.

12. The substrate gripper of claim 11, wherein a portion of the flow of air is directed around the edge of the gripper body toward a vacuum port disposed in a bottom of the gripper body, and wherein the portion of the flow of air diverts from the flow of air within an outer radius of the substrate.

13. The substrate gripper of claim 10, further comprising:
a sonotrode configured to create ultrasonic vibrations that repels the substrate from the gripper body.

14. The substrate gripper of claim 10, wherein supporting of the substrate by vacuum is performed based on the distance between the bottom of the base and the object disposed beneath the gripper body.

15. A factory interface, comprising:
a substrate gripper, comprising:
a gripper body having a base configured to support a substrate by vacuum;
a bowl-shaped collector coupled with the gripper body and configured to collect a flow of air; and
a bell-shaped flow cone coupled with the gripper body and configured to direct the flow of air toward an edge of the gripper body.

16. The factory interface of claim 15, wherein the base of the gripper body comprises a beveled edge.

17. The factory interface of claim 15, wherein the substrate gripper further comprises:
a sonotrode configured to create ultrasonic vibrations that repels the substrate from the gripper body.

18. The factory interface of claim 15, wherein a portion of the flow of air is directed around the edge of the gripper body toward a vacuum port disposed in a bottom of the gripper body, and wherein the portion of the flow of air diverts from the flow of air within an outer radius of the substrate.

19. The factory interface of claim 15, wherein the substrate gripper further comprises:
one or more proximity sensors disposed within the gripper body, wherein the one or more proximity sensors are configured to sense a distance between a bottom of the base and an object disposed beneath the gripper body.

20. The factory interface of claim 15, further comprising:
an aligner station configured to align the substrate to a target alignment, wherein the aligner station is disposed within the factory interface coaxial with the substrate gripper.
